(19) United States
(12) Patent Application Publication
(10) Pub. No.: US 2023/0203299 A1
(43) Pub. Date: Jun. 29, 2023

(54) RESIST UNDERLAYER FILM- FORMING COMPOSITION USING DIARYLMETHANE DERIVATIVE

(71) Applicant: NISSAN CHEMICAL CORPORATION, Tokyo (JP)

(72) Inventors: Hikaru TOKUNAGA, Toyama-shi (JP); Makoto NAKAJIMA, Toyama-shi (JP)

(73) Assignee: NISSAN CHEMICAL CORPORATION, Tokyo (JP)

(21) Appl. No.: 17/927,476

(22) PCT Filed: Jun. 17, 2021
(86) PCT No.: PCT/JP2021/022979

§ 371 Date: Nov. 23, 2022

(30) Foreign Application Priority Data
Jun. 19, 2020 (JP) 2020-106318

(51) Int. Cl. C08L 65/02; C08G 61/12; H01L 21/311; H01L 21/3065; H01L 21/308

(52) U.S. Cl. CPC C08L 65/02; C08G 61/127; C08G 61/124; H01L 21/31138; H01L 21/31144; H01L 21/3065; H01L 21/3081; H01L 21/3086; C08L 2203/20; H01L 21/0276

(57) ABSTRACT

A resist underlayer film forming composition capable of forming a flat film that exhibits high etching resistance, a good dry etching rate ratio and a good optical constant, while having good coverage even with respect to a so-called multileveled substrate and having a small difference in the film thickness after embedding. Also, a method for producing a polymer that is suitable for the resist underlayer film forming composition; a resist underlayer film which uses the resist underlayer film forming composition; and a method for producing a semiconductor device. This resist underlayer film forming composition contains: a reaction product of an aromatic compound (A) that has from 6 to 120 carbon atoms, and a compound that is represented by formula (1); and a solvent.

### TECHNICAL FIELD

The present invention relates to a resist underlayer film-forming composition capable of forming a flat film that exhibits a high etching resistance and good optical constants, while having good coatability even with respect to the so-called stepped substrate and having high gap-filling properties on a micropattern. The present invention also relates to a method for producing a polymer suitably used in the resist underlayer film-forming composition, to a resist underlayer film formed using the resist underlayer film-forming composition, and to a method for manufacturing a semiconductor device.

### BACKGROUND ART

In recent years, resist underlayer film materials for multilayer resist processes are required to function as antireflection films particularly in short-wavelength exposure, to have appropriate optical constants, and also to exhibit an etching resistance during the processing of substrates. The use of polymers that have repeating units containing a benzene ring has been proposed (Patent Literature 1).

### CITATION LIST

### Patent Literature

Patent Literature 1: JP 2004-354554 A

### SUMMARY OF INVENTION

### Technical Problem

To cope with the need for thinner resist layers stemming from the miniaturization of resist patterns, a lithography process is known, in which at least two resist underlayer films are formed and the resist underlayer films are used as mask materials. In this process, at least one organic film (organic underlayer film) and at least one inorganic underlayer film are formed on a semiconductor substrate. The inorganic underlayer film is patterned using as a mask a resist pattern that has been formed in an upper resist film, and the resultant pattern is used as a mask in the patterning of the organic underlayer film. The pattern formed in this manner attains a high aspect ratio. For example, the materials for forming the at least two layers are a combination of an organic resin (for example, an acrylic resin or a novolac resin) and an inorganic material (such as a silicon resin (for example, organopolysiloxane) or an inorganic silicon compound (for example, SiON or SiO₂)). In recent years, a double patterning technique has widely been used, in which two times of lithography and two times of etching are carried out in order to obtain a single pattern, wherein the multilayer process described above is used in each of the steps. Here, the organic film that is formed after the first patterning is required to be capable of planarizing the difference in level and also to be capable of filling gaps in the micropattern.

Problematically, the coatability of resist underlayer film-forming compositions is poor with respect to the so-called stepped substrates that have unevenness due to the difference in height or density of resist patterns disposed on workpiece substrates, and the films formed therefrom tend to fail to fill gaps in the micropatterns.

The present invention has been made based on the solution to these problems. An object of the present invention is therefore to provide a resist underlayer film-forming composition capable of forming a flat film that exhibits a high etching resistance, good dry etching rate ratio and optical constants, and exhibits good coatability even with respect to the so-called stepped substrates and having high gap-filling properties on a micropattern. Other objects of the present invention are to provide a resist underlayer film formed using the resist underlayer film-forming composition, and to provide a method for manufacturing a semiconductor device using the resist underlayer film-forming composition.

### Solution to Problem

The present invention embraces the following.

[1] A resist underlayer film-forming composition comprising a solvent and a reaction product of a C6-C120 aromatic compound (A) with a compound represented by formula (1) below,

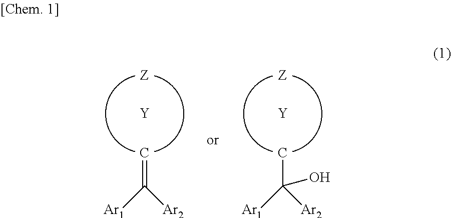

[in formula (1), Z denotes —(C═O)— or —C(—OH)—; Ar₁ and Ar₂ each independently denote an optionally substituted phenyl, naphthyl, anthracenyl or pyrenyl group; and ring Y denotes an optionally substituted cyclic aliphatic, an optionally substituted aromatic, or an optionally substituted cyclic aliphatic-aromatic fused ring.].

[2] The resist underlayer film-forming composition according to [1], wherein the reaction product is such that one carbon atom in ring Y is linked to one molecule of aromatic compound (A), and one carbon atom in Ar₁ or Ar₂ is linked to another molecule of aromatic compound (A).

[3] The resist underlayer film-forming composition according to [1] or [2], wherein the compound represented by formula (1) is represented by formula (1a) below:

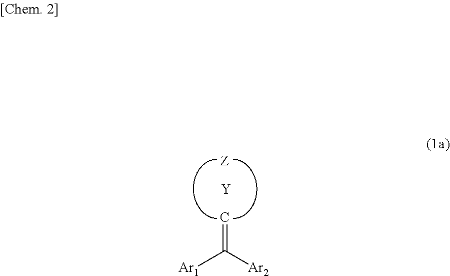

[in formula (1a), Z denotes —(C═O)—; Ar₁ and Ar₂ each independently denote an optionally substituted phenyl, naphthyl, anthracenyl or pyrenyl group; and ring Y denotes an optionally substituted cyclic aliphatic, or an optionally substituted cyclic aliphatic-aromatic fused ring.].

[4] The resist underlayer film-forming composition according to [1], wherein the reaction product is such that one carbon atom in ring Y is linked to two molecules of aromatic compound (A).

[5] The resist underlayer film-forming composition according to [4], wherein ring Y in formula (1a) is a fused ring structure containing a cyclohexene ring.

[6] The resist underlayer film-forming composition according to [5], wherein ring Y in formula (1a) denotes a cyclic aliphatic-aromatic fused ring.

[7] The resist underlayer film-forming composition according to any one of [1] to [3], wherein the compound represented by formula (1) is represented by formula (1b) below:

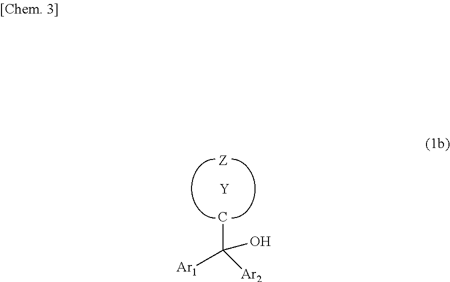

[in formula (1b), Z denotes —C(—OH)— Ar₁ and Ar₂ each independently denote an optionally substituted phenyl, naphthyl, anthracenyl or pyrenyl group; and ring Y denotes an optionally substituted cyclic aliphatic, an optionally substituted aromatic, or an optionally substituted cyclic aliphatic-aromatic fused ring.].

[8] The resist underlayer film-forming composition according to [7], wherein formula (1b) is an aromatic compound.

[9] The resist underlayer film-forming composition according to [8], wherein Y in formula (1b) comprises a naphthalene ring.

[10] The resist underlayer film-forming composition according to any one of [1] to [9], wherein Ar₁ and Ar₂ in formula (1) each independently denote an optionally hydroxy-substituted phenyl or naphthyl group.

[11] The resist underlayer film-forming composition according to any one of [1] to [10], wherein aromatic compound (A) contains at least one benzene ring, at least one naphthalene ring, at least one anthracene ring, at least one pyrene ring, or a combination thereof.

[12] The resist underlayer film-forming composition according to any one of [1] to [10], wherein aromatic compound (A) contains at least two benzene rings, at least two naphthalene rings, at least two anthracene rings, at least two pyrene rings, or a combination thereof.

[13] The resist underlayer film-forming composition according to any one of [1] to [12], further comprising a crosslinking agent.

[14] The resist underlayer film-forming composition according to any one of [1] to [13], further comprising an acid and/or an acid generator.

[15] The resist underlayer film-forming composition according to [1] to [14], wherein the solvent has a boiling point of 160° C. or above.

[16] A resist underlayer film comprising a baked product of a coating film comprising the resist underlayer film-forming composition according to any one of [1] to [15].

[17] A method for manufacturing a semiconductor device, comprising the steps of:

forming on a semiconductor substrate a resist underlayer film using the resist underlayer film-forming composition according to any one of [1] to [15];

forming a resist film on the resist underlayer film;

forming a resist pattern by irradiation with light or electron beam followed by development;

etching the underlayer film through the resist pattern; and

processing the semiconductor substrate through the patterned underlayer film.

[18] The method for manufacturing a semiconductor device according to [17], wherein the step of forming a resist underlayer film is performed by a nanoimprinting method.

### Advantageous Effects of Invention

The resist underlayer film-forming composition of the present invention can form a resist underlayer film that exhibits not only a high etching resistance and good optical constants, but also a high coatability even with respect to the so-called stepped substrate and attains high gap-filling properties on a micropattern, thus allowing for finer substrate processing.

In particular, the resist underlayer film-forming composition of the present invention is effective in a lithography process for the purpose of reducing the resist film thickness, in which at least two resist underlayer films are formed and the resist underlayer films are used as etching masks.

### DESCRIPTION OF EMBODIMENTS

[Resist Underlayer Film-Forming Composition]

A resist underlayer film-forming composition according to the present invention contains a solvent and a reaction product of a C6-C120 aromatic compound (A) with a compound represented by formula (1) below.

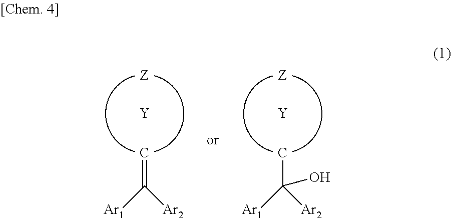

[In formula (1), Z denotes —(C═O)— or —C(—OH)—; Ar₁ and Ar₂ each independently denote an optionally substituted phenyl, naphthyl, anthracenyl or pyrenyl group; and ring Y denotes an optionally substituted cyclic aliphatic, an optionally substituted aromatic, or an optionally substituted cyclic aliphatic-aromatic fused ring.]

The components will be described sequentially below.

[C6-C120 Aromatic Compounds (A)]

The C6-C120 aromatic compound (A) may be:

(a) a monocyclic compound such as benzene, phenol or phloroglucinol,

(b) a fused ring compound such as naphthalene, dihydroxynaphthalene, naphthol, 9,10-anthraquinone or indenofluorenedione,

(c) a heterocyclic compound such as furan, thiophene, pyridine, carbazole, phenothiazine, phenoxazine or indolocarbazole,

(d) a compound, in which any of the compounds (a) to (c) are linked together via a single bond between their aromatic rings, such as biphenyl, phenylindole, 9,9-bis(4-hydroxyphenyl)fluorene, α,α,α′,α′-tetrakis(4-hydroxyphenyl)-p-xylene or 9,9-fluorenylidene-bisnaphthol, or

(e) a compound, in which any of the compounds (a) to (d) are linked together via a spacer, for example, —(CH₂)ₙ— (n=1 to 20), —CH═CH—, —C≡C—, —N═N—, —NH—, —NR—, —NHCO—, —NRCO—, —S—, —COO—, —OCO—, —O—, —CO— or —CH═N—, between their aromatic rings, such as phenylnaphthylamine.

Examples of the aromatic compounds include benzene, thiophene, furan, pyridine, pyrimidine, pyrazine, pyrrole, oxazole, thiazole, imidazole, naphthalene, anthracene, quinoline, carbazole, fluorene, quinazoline, purine, indolizine, benzothiophene, benzofuran, indole, phenylindole and acridine.

Aromatic compound (A) may be an aromatic compound containing an amino group, a hydroxy group, or both. Aromatic compound (A) may be an arylamine compound, a phenol compound, or aromatic compounds including both of these compounds.

An aromatic amine or a phenolic hydroxy group-containing compound is preferable.

Examples of the aromatic amines include aniline, diphenylamine, phenylnaphthylamine, hydroxydiphenylamine, phenylnaphthylamine, N,N′-diphenylethylenediamine and N,N′-diphenyl-1,4-phenylenediamine.

Examples of the phenolic hydroxy group-containing compounds include phenol, dihydroxybenzene, trihydroxybenzene, hydroxynaphthalene, dihydroxynaphthalene, trihydroxynaphthalene, tris(4-hydroxyphenyl)methane, tris(4-hydroxyphenyl)ethane, 1,1,2,2-tetrakis(4-hydroxyphenyl)ethane and polynuclear phenols.

Examples of the polynuclear phenols include dihydroxybenzene, trihydroxybenzene, hydroxynaphthalene, dihydroxynaphthalene, trihydroxynaphthalene, tris(4-hydroxyphenyl)methane, tris(4-hydroxyphenyl)ethane, 2,2′-biphenol and 1,1,2,2-tetrakis(4-hydroxyphenyl)ethane.

The C6-C120 aromatic compound (A) may be substituted with a C1-C20 alkyl group, a C2-C10 alkenyl group, a C2-C10 alkynyl group, a fused ring group, a heterocyclic group, a hydroxy group, a formyl group, an amino group, a nitro group, an ether group, an alkoxy group, a cyano group or a carboxyl group in place of a hydrogen atom.

Examples of the C1-C20 alkyl groups include optionally substituted, linear or branched alkyl groups such as, for example, methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecylnonyl group, undecyl group, dodecyl group, tridecyl group, tetradecyl group, pentadecyl group, hexadecyl group, heptadecyl group, octadecyl group, nonadecyl group and eicosyl group. C1-C12 alkyl groups are preferable, C1-C8 alkyl groups are more preferable, and C1-C4 alkyl groups are still more preferable.

Examples of the C2-C10 alkenyl groups and the C2-C10 alkynyl groups include optionally substituted, linear or branched alkenyl groups and alkynyl groups such as, for example, vinyl group, ethynyl group, 2-propenyl group, 2-propynyl group, 2-butenyl group, 2-butynyl group, 3-butenyl group and 3-butynyl group.

Examples of the C1-C20 alkyl groups interrupted with an oxygen atom, a sulfur atom or an amide bond include those containing a structural unit —CH₂—O—, —CH₂—S—, —CH₂—NHCO— or —CH₂—CONH—. The alkyl groups may contain one, or two or more units represented by —O—, —S—, —NHCO— or —CONH—. Specific examples of the C1-C20 alkyl groups interrupted with an —O—, —S—, —NHCO— or —CONH— unit include methoxy group, ethoxy group, propoxy group, butoxy group, methylthio group, ethylthio group, propylthio group, butylthio group, methylcarbonylamino group, ethylcarbonylamino group, propylcarbonylamino group, butylcarbonylamino group, methylaminocarbonyl group, ethylaminocarbonyl group, propylaminocarbonyl group and butylaminocarbonyl group, and further include methyl group, ethyl group, propyl group, butyl group, pentyl group, hexyl group, heptyl group, octyl group, nonyl group, decyl group, dodecyl group and octadecyl group, each of which is substituted with a substituent such as a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group or an ethylaminocarbonyl group. Methoxy group, ethoxy group, methylthio group and ethylthio group are preferable, and methoxy group and ethoxy group are more preferable.

Examples of the C2-C10 alkenyl groups and the C2-C10 alkynyl groups, each of which may be interrupted with an oxygen atom, include 2-propenyloxy group, 2-propynyloxy group, 3-butenyloxy group, 3-butynyloxy group and 2-(ethynyloxy)ethoxy group.

The fused ring groups are substituents derived from a fused ring compound. Specific examples thereof include phenyl group, naphthyl group, anthracenyl group, phenanthrenyl group, naphthacenyl group, triphenylenyl group, pyrenyl group and chrysenyl group. Of these, phenyl group, naphthyl group, anthracenyl group and pyrenyl group are preferable.

The heterocyclic groups are substituents derived from a heterocyclic compound. Specific examples thereof include thiophene group, furan group, pyridine group, pyrimidine group, pyrazine group, pyrrole group, oxazole group, thiazole group, imidazole group, quinoline group, carbazole group, quinazoline group, purine group, indolizine group, benzothiophene group, benzofuran group, indole group, acridine group, isoindole group, benzimidazole group, isoquinoline group, quinoxaline group, cinnoline group, pteridine group, chromene group (benzopyran group), isochromene group (benzopyran group), xanthene group, thiazole group, pyrazole group, imidazoline group and azine group. Of these, thiophene group, furan group, pyridine group, pyrimidine group, pyrazine group, pyrrole group, oxazole group, thiazole group, imidazole group, quinoline group, carbazole group, quinazoline group, purine group, indolizine group, benzothiophene group, benzofuran group, indole group and acridine group are preferable, and thiophene group, furan group, pyridine group, pyrimidine group, pyrrole group, oxazole group, thiazole group, imidazole group and carbazole group are most preferable.

The nitrogen atom on the heterocycle may be substituted with a C2-C10 alkenyl group or a C2-C10 alkynyl group.

The molecules of the aromatic compounds mentioned above may be linked together by a single bond or a spacer.

Examples of the spacers include —(CH₂)ₙ— (n=1 to 20), —CH═CH—, —C≡C—, —N═N—, —NH—, —NR—, —NHCO—, —NRCO—, —S—, —COO—, —OCO—, —O—, —CO—, -Ph-, -Ph-Ph-, -Ph-O-Ph- (Ph=C₆H₄), —CH═N—, and combinations of two or more of the above spacers. Two or more of these spacers may be linked together.

Examples of substituents R on the nitrogen atom include those mentioned hereinabove as examples of the optionally substituted, linear or branched C1-C20 alkyl groups.

Aromatic compound (A) preferably contains at least one benzene ring, at least one naphthalene ring, at least one anthracene ring, at least one pyrene ring, or a combination thereof, and more preferably contains at least two benzene rings, at least two naphthalene rings, at least two anthracene rings, at least two pyrene rings, or a combination thereof.

Aromatic compound (A) may be a fused ring compound of two or more kinds of the aromatic compounds (A) as long as the number of carbon atoms does not exceed 120.

Examples of aromatic compounds (A) also include those compounds illustrated below:

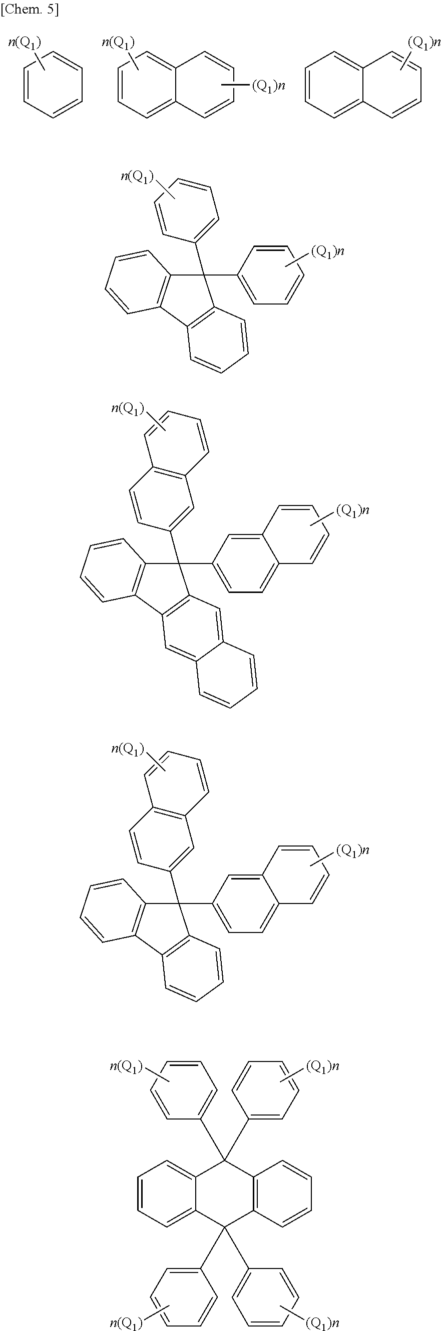

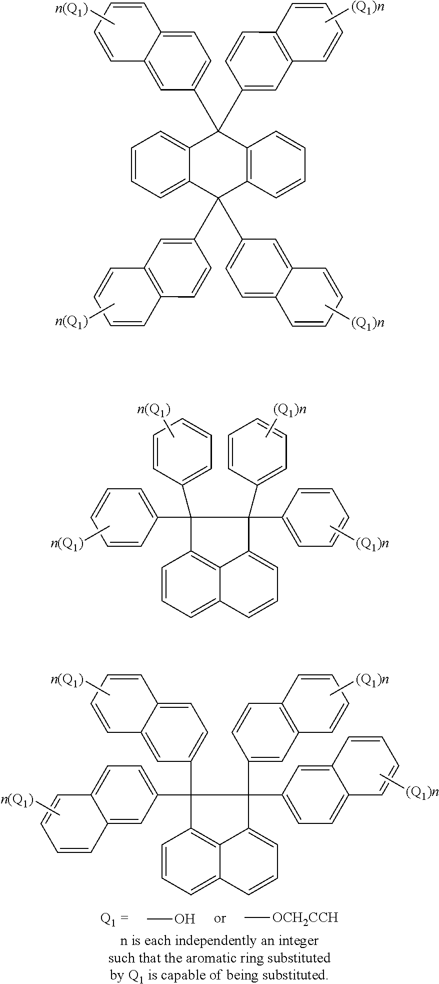

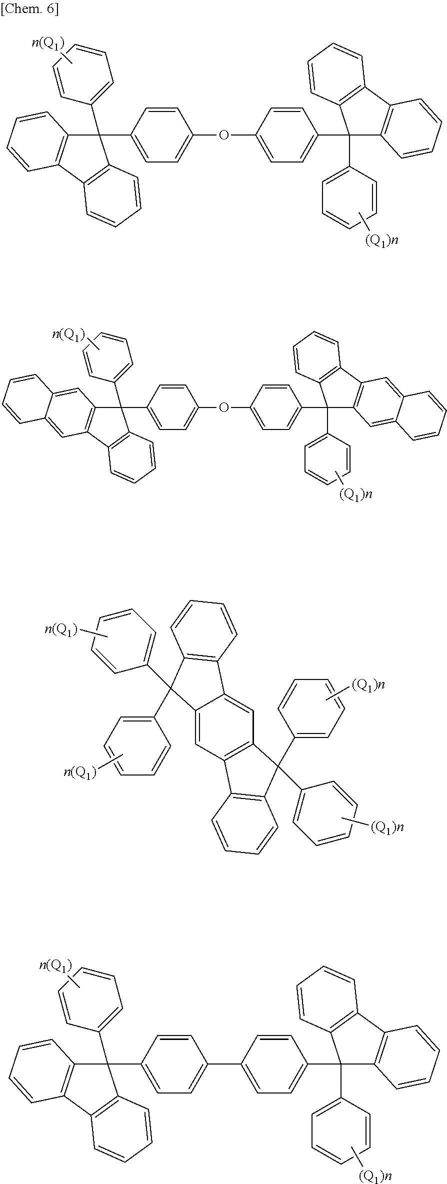

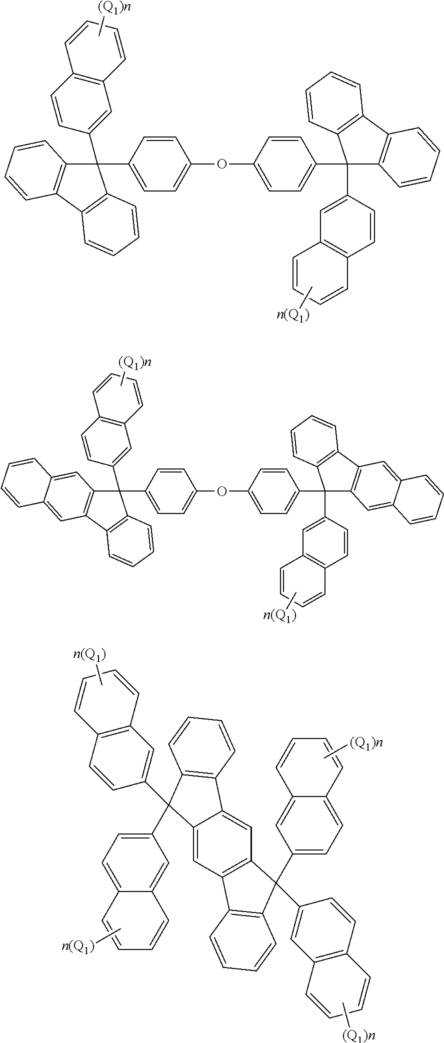

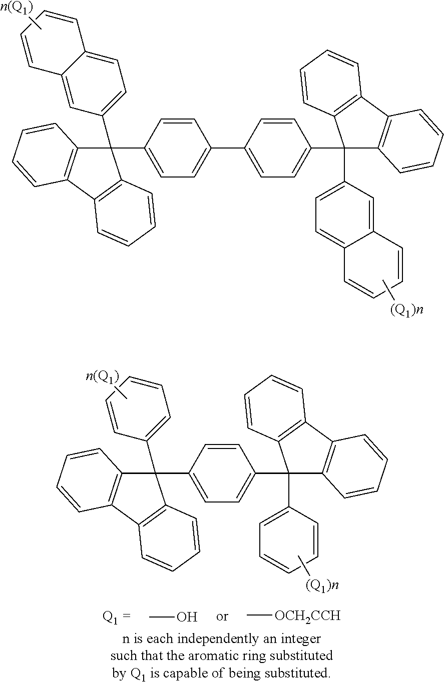

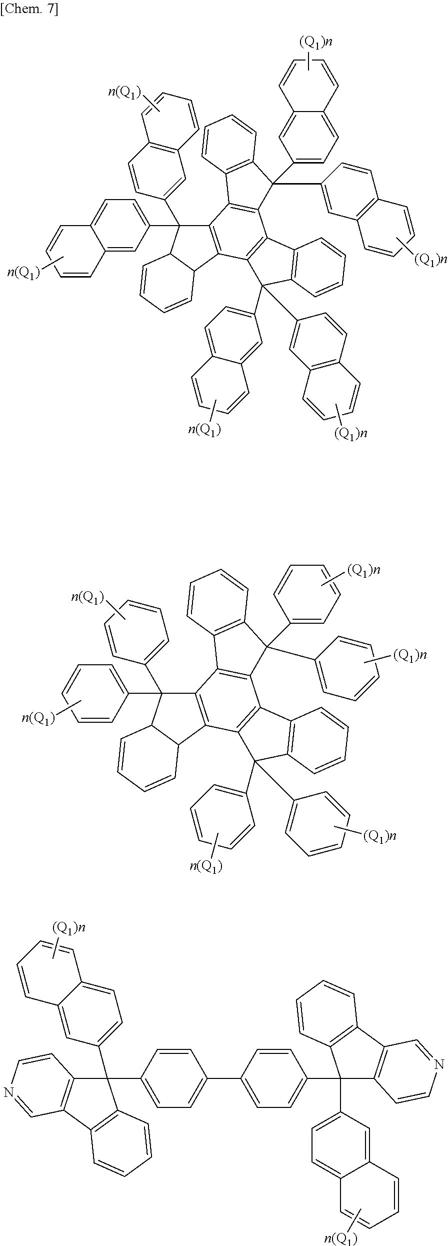

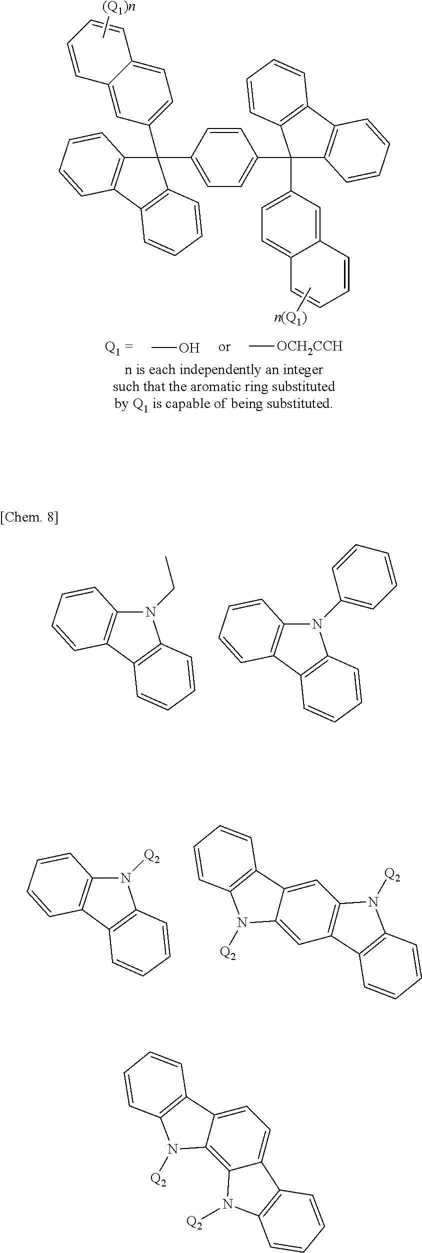

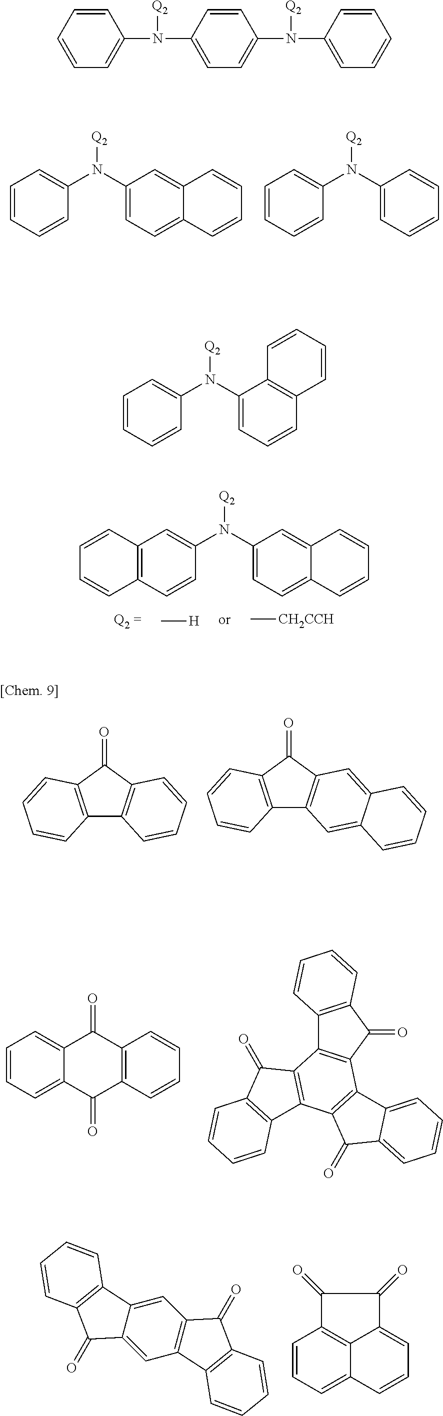

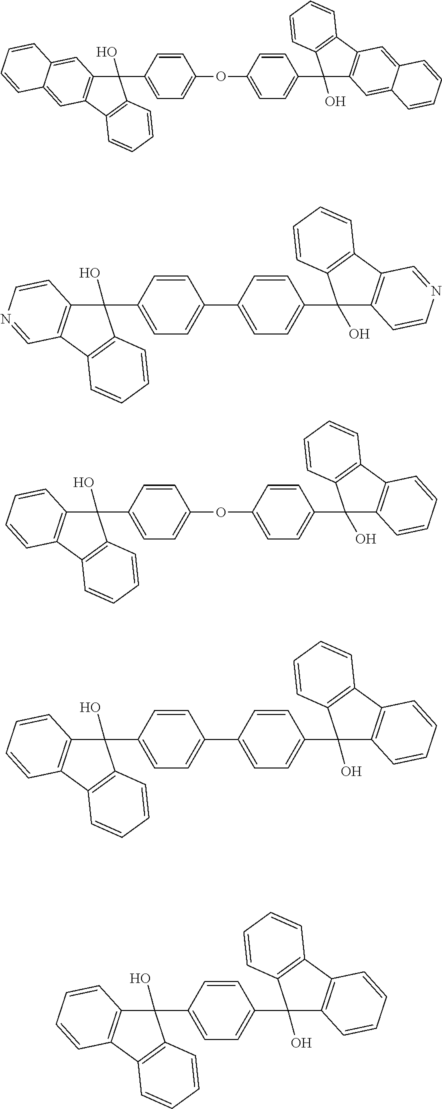 [SMILES: OC1(c2ccc(Oc3ccc(C4(O)c5ccccc5-c5cc6ccccc6cc54)cc3)cc2)c2ccccc2-c2cc3ccccc3cc21 ; OC1(c2ccc(-c3ccc(C4(O)c5ccccc5-c5cnccc54)cc3)cc2)c2ccccc2-c2cnccc21 ; OC1(c2ccc(Oc3ccc(C4(O)c5ccccc5-c5ccccc54)cc3)cc2)c2ccccc2-c2ccccc21 ; OC1(c2ccc(-c3ccc(C4(O)c5ccccc5-c5ccccc54)cc3)cc2)c2ccccc2-c2ccccc21 ; OC1(c2ccc(C3(O)c4ccccc4-c4ccccc43)cc2)c2ccccc2-c2ccccc21]

Preferred examples of aromatic compounds (A) include, but are not limited to, 1-naphthaldehyde, 1-pyrenecarboxyaldehyde, 9-fluorenone, carbazole, N-phenyl-1-naphthylamine, 2-phenylindole, 2,2′-biphenol, 1,5-dihydroxynaphthalene and 9,9-bis(4-hydroxyphenyl)fluorene.

Aromatic compounds (A) may be used each alone or in combination of two or more. Preferably, one or two aromatic compounds (A) are used.

[Compound Represented by Formula (1)]

In formula (1) above, Ar₁ and Ar₂ each independently denote an optionally substituted phenyl, naphthyl, anthracenyl or pyrenyl group.

Examples of the substituent include a C1-C20 alkyl group optionally substituted with a hydroxy group or a carbonyl group and optionally interrupted with an oxygen atom or a sulfur atom; a hydroxy group; an oxo group; a carboxy groups: a cyano group; a nitro group; a sulfo group; a C1-C6 acyl group; a C1-C6 alkoxy group; a C1-C6 alkoxycarbonyl group; an amino group; a glycidyl group; a C6-C20 aryl group; a C2-C10 alkenyl group; and a C2-C10 alkynyl group. These substituents may be bonded to Ar₁ and/or Ar₂ via an oxygen atom.

Examples of the C1-C20 alkyl group are the same as mentioned with respect to the C6-C120 aromatic compounds (A). Examples of the C1-C6 acyl group include formyl group and acetyl group. Examples of the C1-C6 alkoxy group include methoxy group, ethoxy group, n-propoxy group and isopropoxy group. Examples of the C1-C6 alkoxycarbonyl group include methoxycarbonyl group, ethoxycarbonyl group, n-propoxycarbonyl group and isopropoxycarbonyl group. Examples of the C6-C20 aryl group include phenyl group, o-methylphenyl group, m-methylphenyl group, p-methylphenyl group, o-methoxyphenyl group, p-methoxyphenyl group, a-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, 9-phenanthryl group and fluorene group. Examples of the C2-C10 alkenyl group include vinyl group and allyl group. Examples of the C2-C10 alkynyl group include ethynyl group. The aforementioned description of heteroatoms, cyclic compounds, coupled rings and fused rings also applies here.

Preferably, Ar₁ and Ar₂ in formula (1) each independently denote an optionally hydroxy-substituted phenyl or naphthyl group.

In formula (1), ring Y denotes an optionally substituted cyclic aliphatic, an optionally substituted aromatic, or an optionally substituted cyclic aliphatic-aromatic fused ring.

Examples of the cyclic aliphatics include, but are not limited to, monocycles such as cyclohexane and cyclohexene, polycycles such as bicyclo[3.2.1]octane and bicyclo[2.2.1]hepta-2-ene, and spirocycles such as spirobicyclopentane.

Examples of the aromatics include, but are not limited to, benzene, indene, naphthalene, azulene, anthracene, phenanthrene, naphthacene, triphenylene, pyrene and chrysene.

Examples of the cyclic aliphatic-aromatic fused rings include, but are not limited to, benzo[a]cyclohexene, benzo[b]cyclohexene, 1,2,3,4-tetrahydronaphthalene and fluorene.

Examples of the substituents are the same as mentioned with respect to Ar₁ and Ar₂.

Preferably, the compound represented by formula (1) is allowed to react with aromatic compound (A) with the result that one carbon atom in ring Y is linked to one molecule of aromatic compound (A), and one carbon atom in Ar₁ or Ar₂ is linked to another molecule of aromatic compound (A), or with the result that one carbon atom in ring Y is linked to two molecules of aromatic compound (A).

Preferably, the compound represented by formula (1) is represented by formula (1a) below:

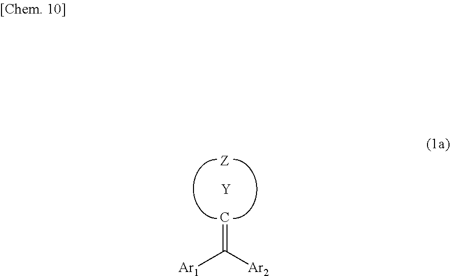

[In formula (1a), Z denotes —(C═O)—; Ar₁ and Ar₂ each independently denote an optionally substituted phenyl, naphthyl, anthracenyl or pyrenyl group; and ring Y denotes an optionally substituted cyclic aliphatic, or an optionally substituted cyclic aliphatic-aromatic fused ring.]

Examples of Ar₁, Ar₂, Y and their substituents are the same as mentioned hereinabove in relation to formula (1).

Preferably, ring Y in formula (1a) is a fused ring structure containing a cyclohexene ring. Preferably, ring Y in formula (1a) denotes a cyclic aliphatic-aromatic fused ring. More preferably, ring Y in formula (1a) denotes a cyclohexene-aromatic fused ring. Most preferably, ring Y in formula (1a) denotes a cyclohexene-benzene fused ring.

Preferably, the compound represented by formula (1) is represented by formula (1b) below:

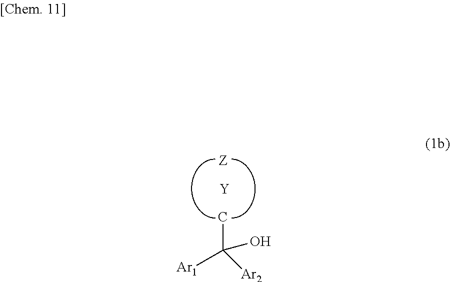

[In formula (1b), Z denotes —C(—OH)—; Ar₁ and Ar₂ each independently denote an optionally substituted phenyl, naphthyl, anthracenyl or pyrenyl group; and ring Y denotes an optionally substituted cyclic aliphatic, an optionally substituted aromatic, or an optionally substituted cyclic aliphatic-aromatic fused ring.]

Examples of Ar₁, Ar₂, Y and their substituents are the same as mentioned hereinabove in relation to formula (1).

Preferably, formula (1b) is an aromatic compound. More preferably, Y in formula (1b) contains a naphthalene ring. Most preferably, Y in formula (1b) is a naphthalene ring.

Some particularly preferred compounds represented by formula (1) are p-naphtholbenzein and α-naphtholbenzein.

The compounds represented by formula (1) may be used each alone or in combination of two or more. Preferably, one or two compounds represented by formula (1) are used. For example, one, or two or more compounds represented by formula (1a), and one, or two or more compounds represented by formula (1b) may be used in combination.

[Reaction Product]

The reaction of aromatic compound (A) with the carbonyl group or the hydroxymethylene group present in the compound represented by formula (1) gives a reaction product (a polymer), in which one carbon atom in ring Y of the compound represented by formula (1) is linked to one molecule of aromatic compound (A), and one carbon atom in Ar₁ or Ar₂ is linked to another molecule of aromatic compound (A), or gives a reaction product (a polymer), in which one carbon atom in ring Y of the compound represented by formula (1) is linked to two molecules of aromatic compound (A).

As the acid catalyst used for the reaction, for example, a mineral acid such as sulfuric acid, phosphoric acid or perchloric acid; an organic sulfonic acid such as p-toluenesulfonic acid, p-toluenesulfonic acid monohydrate or methanesulfonic acid; or a carboxylic acid such as formic acid or oxalic acid is used. The amount of the acid catalyst used is variable and is selected in accordance with the type of the acid used. The amount is usually within the range of 0.001 to 10000 parts by mass, preferably 0.01 to 1000 parts by mass, and more preferably 0.1 to 100 parts by mass, with respect to 100 parts by mass of aromatic compound (A).

The condensation reaction and the addition reaction mentioned above may take place in the absence of a solvent, but are usually performed using a solvent. Any solvents that do not inhibit the reaction may be used. Examples thereof include ethers such as 1,2-dimethoxyethane, diethylene glycol dimethyl ether, propylene glycol monomethyl ether, tetrahydrofuran and dioxane; esters such as propylene glycol monomethyl ether acetate; and ketones such as N-methylpyrrolidone.

The reaction temperature is usually a reflux temperature of the reaction mixture, and is preferably within the range of 40° C. to 200° C. The reaction time is variable and is selected in accordance with the reaction temperature, but is usually about within the range of 30 minutes to 50 hours.

The weight average molecular weight Mw of the polymer obtained as described above is within the range of usually 200 to 10,000, and preferably 300 to 5,000, or 400 to 4,000.

Some reaction products suitably used in the present invention will be described in Examples.

[Solvent]

The solvent used in the resist underlayer film-forming composition of the present invention may be any solvent without limitation that can dissolve the reaction product described above. In particular, considering the fact that the resist underlayer film-forming composition of the present invention is used as a uniform solution, it is recommended to use a solvent commonly used in the lithographic process in combination.

Examples of the solvent include methyl cellosolve acetate, ethyl cellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol and γ-butyrolactone. The solvents may be used each alone or in combination of two or more.

Further, the following compounds described in WO 2018/131562 A1 may be used.

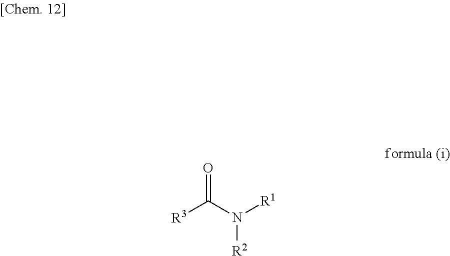

(In formula (i), R¹, R² and R³ are each a hydrogen atom or a C1-C20 alkyl group optionally interrupted with an oxygen atom, a sulfur atom or an amide bond, and may be the same as or different from one another and may be bonded to one another to form a ring structure.)

Examples of the C1-C20 alkyl groups include optionally substituted, linear or branched alkyl groups such as, for example, methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecylnonyl group, undecyl group, dodecyl group, tridecyl group, tetradecyl group, pentadecyl group, hexadecyl group, heptadecyl group, octadecyl group, nonadecyl group and eicosyl group. C1-C12 alkyl groups are preferable, C1-C8 alkyl groups are more preferable, and C1-C4 alkyl groups are still more preferable.

Examples of the C1-C20 alkyl groups interrupted with an oxygen atom, a sulfur atom or an amide bond include those containing a structural unit —CH₂—O—, —CH₂—S—, —CH₂—NHCO— or —CH₂—CONH—. The alkyl groups may contain one, or two or more units represented by —O—, —S—, —NHCO— or —CONH—. Specific examples of the C1-C20 alkyl groups interrupted with an —O—, —S—, —NHCO— or —CONH— unit include methoxy group, ethoxy group, propoxy group, butoxy group, methylthio group, ethylthio group, propylthio group, butylthio group, methylcarbonylamino group, ethylcarbonylamino group, propylcarbonylamino group, butylcarbonylamino group, methylaminocarbonyl group, ethylaminocarbonyl group, propylaminocarbonyl group and butylaminocarbonyl group, and further include methyl group, ethyl group, propyl group, butyl group, pentyl group, hexyl group, heptyl group, octyl group, nonyl group, decyl group, dodecyl group and octadecyl group, each of which is substituted with a substituent such as a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group or an ethylaminocarbonyl group. Methoxy group, ethoxy group, methylthio group and ethylthio group are preferable, and methoxy group and ethoxy group are more preferable.

The above solvents have a relatively high boiling point and are therefore effective for imparting high gap-filling properties and high flattening properties to the resist underlayer film-forming composition.

Specific examples of preferred compounds represented by formula (i) are illustrated below.

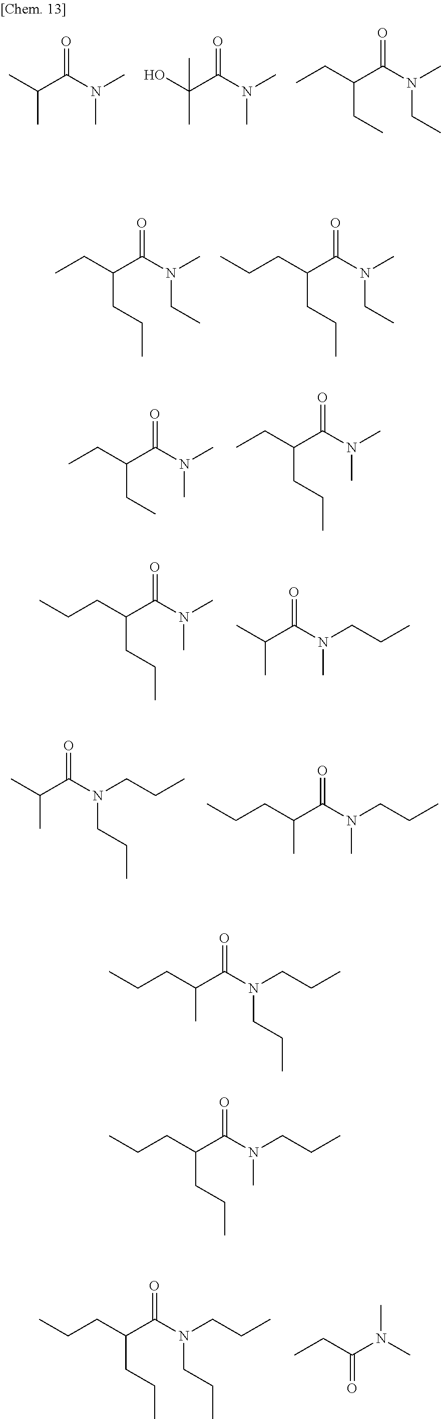

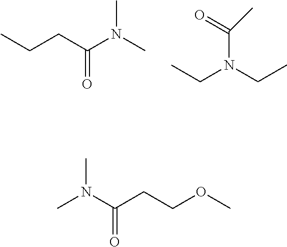

Of the above compounds, preferable are 3-methoxy-N,N-dimethylpropionamide, N,N-dimethylisobutyramide, and the compounds represented by the following formulas:

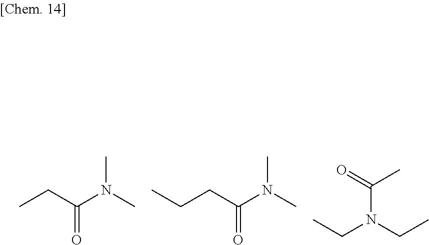

3-Methoxy-N,N-dimethylpropionamide and N,N-dimethylisobutyramide are particularly preferable as the compound represented by formula (i).

The above solvents may be used each alone or in combination of two or more. Of the solvents mentioned above, those having a boiling point of 160° C. or above are preferable, and, for example, propylene glycol monomethyl ether, propylene glycol monomethyl ether acetate, ethyl lactate, butyl lactate, cyclohexanone, 3-methoxy-N,N-dimethylpropionamide, N,N-dimethylisobutyramide, 2,5-dimethylhexane-1,6-diyl diacetate (DAH; CAS: 89182-68-3) and 1,6-diacetoxyhexane (CAS: 6222-17-9) are preferable. Propylene glycol monomethyl ether, propylene glycol monomethyl ether acetate and N,N-dimethylisobutyramide are particularly preferable.

[Crosslinking Agent]

The resist underlayer film-forming composition of the present invention may contain a crosslinking agent. Examples of the crosslinking agent include melamine-based agents, substituted urea-based agents, and polymers thereof. Crosslinking agents having at least two crosslinking substituents are preferable, with examples including methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea and methoxymethylated thiourea. Furthermore, condensates of these compounds may also be used.

The crosslinking agent that is used may be a crosslinking agent having a high heat resistance. The crosslinking agent having a high heat resistance may be preferably a compound that contains in the molecule a crosslinking substituent having an aromatic ring (for example, a benzene ring or a naphthalene ring).

Examples of such compounds include compounds having a partial structure of the following formula (4), and polymers and oligomers having a repeating unit of the following formula (5):

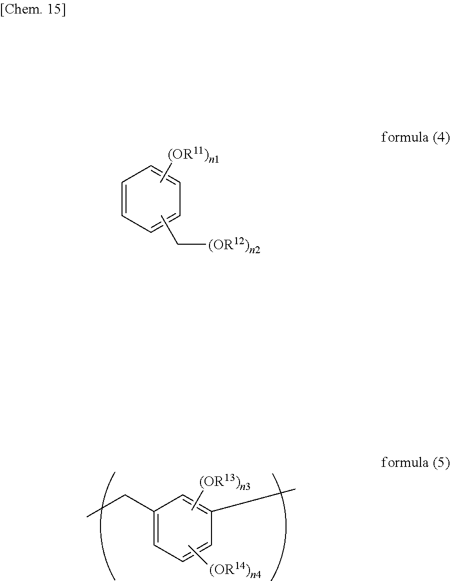

R¹¹, R¹², R¹³ and R¹⁴ are each a hydrogen atom or a C1-C10 alkyl group. Examples of the alkyl groups are the same as mentioned hereinabove.

n1 is an integer of 1 to 4, n2 is an integer of 1 to (5−n1), and (n1+n2) is an integer of 2 to 5. n3 is an integer of 1 to 4, n4 is 0 to (4−n3), and (n3+n4) is an integer of 1 to 4. The number of the repeating unit structure in the oligomers and the polymers may be in the range of 2 to 100, or 2 to 50.

Examples of the compounds, polymers and oligomers having formula (4) or formula (5) are illustrated below.

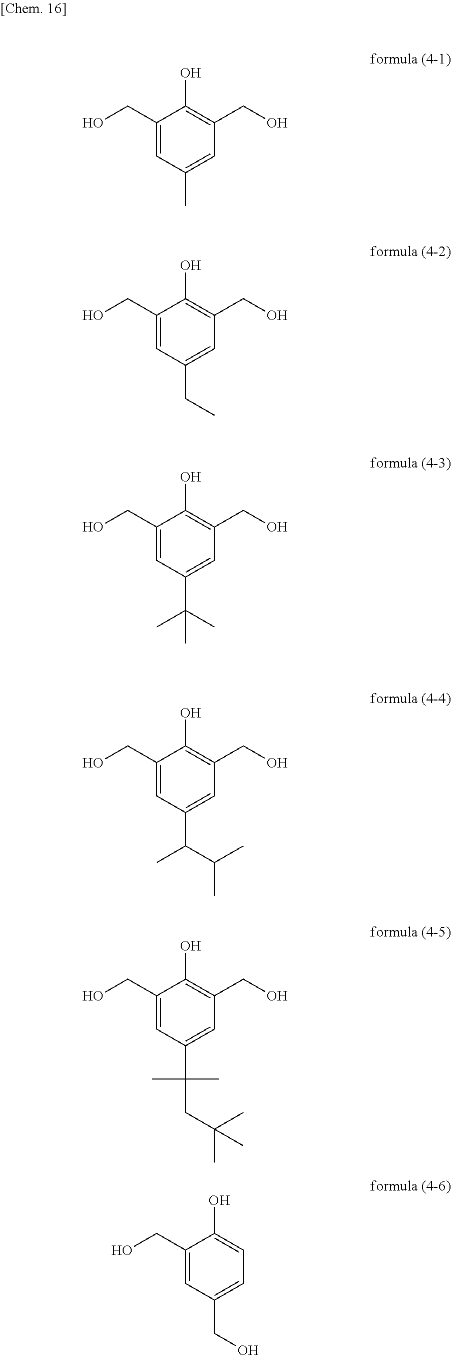

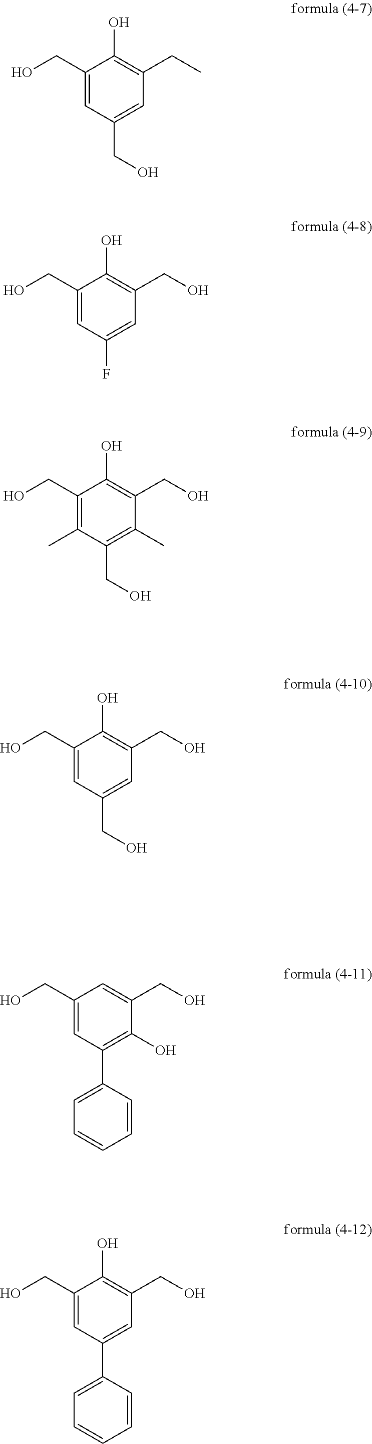 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

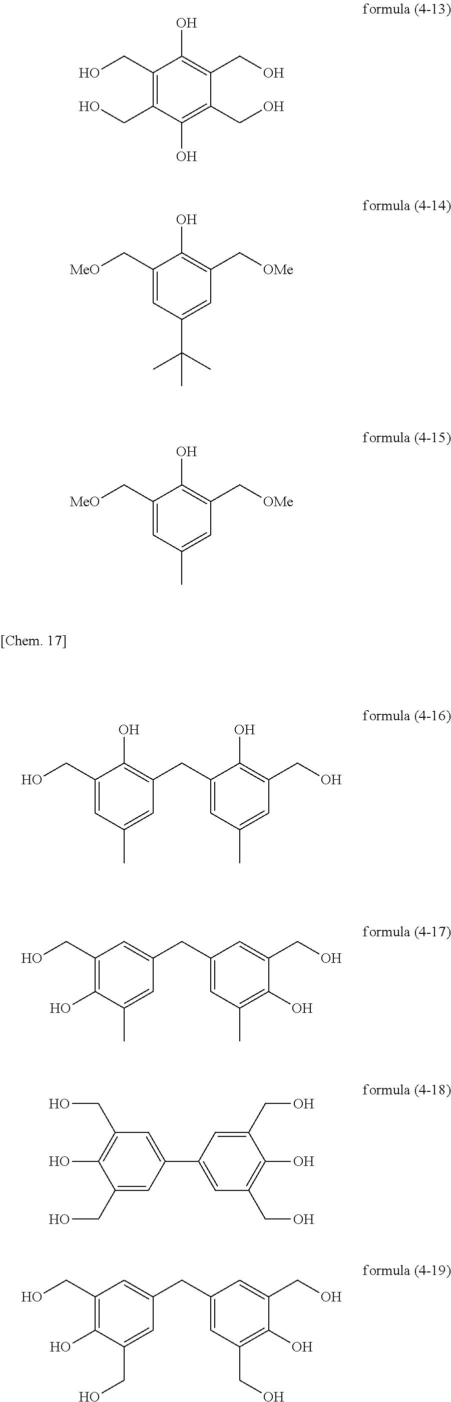

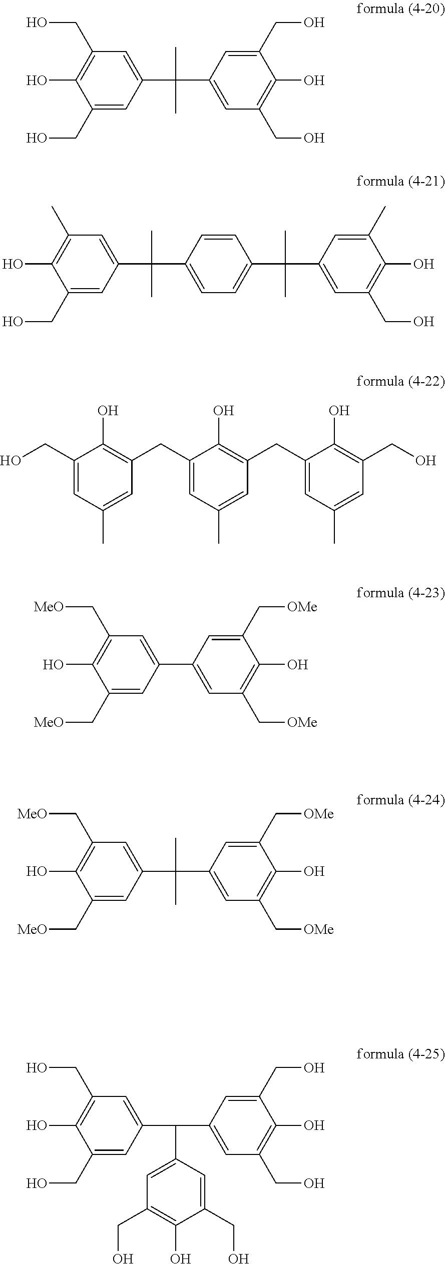 [SMILES: CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O ; Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O]

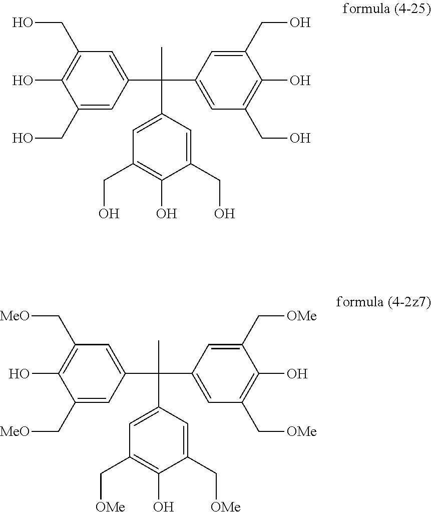 [SMILES: CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The above compounds are commercially available from ASAHI YUKIZAI CORPORATION or Honshu Chemical Industry Co., Ltd. Of the above crosslinking agents, for example, the compound of formula (4-24) is available under the product name TM-BIP-A from ASAHI YUKIZAI CORPORATION.

In addition to the compounds described above, compounds of the following structures may also be used as the crosslinking agent.

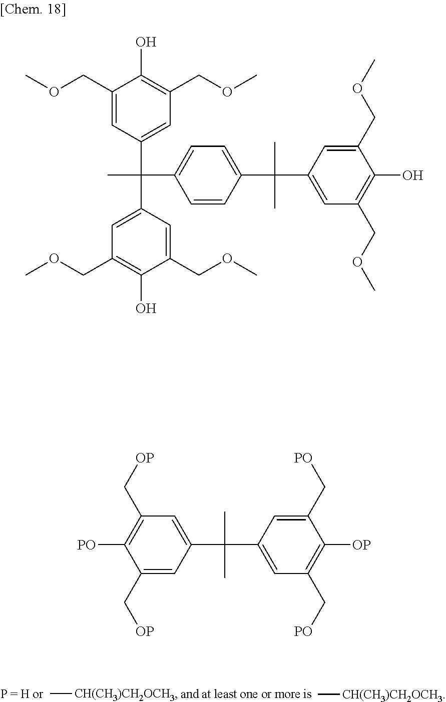

The amount of the cros slinking agent added varies depending on such factors as the type of the coating solvent used, the type of the base substrate used, the solution viscosity that is required and the film shape that is required, but may be within the range of 0.001 to 80% by mass, preferably 0.01 to 50% by mass, and more preferably 0.05 to 40% by mass relative to the total solid content. The above crosslinking agents may be crosslinked by self-condensation, but, when the reaction product of the present invention has a crosslinking substituent, they can undergo a crosslinking reaction with the crosslinking substituents.

[Acid and/or Salt Thereof, and/or Acid Generator]

The resist underlayer film-forming composition of the present invention may contain an acid and/or a salt thereof, and/or an acid generator.

Examples of the acid include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, carboxylic acid compounds such as citric acid, benzoic acid, hydroxybenzoic acid and naphthalenecarboxylic acid, and inorganic acids such as hydrochloric acid, sulfuric acid, nitric acid and phosphoric acid.

The salt may be a salt of any of the acids mentioned above. Examples of the salt that may be suitably used include, but are not limited to, ammonia derivative salts such as trimethylamine salts and triethylamine salts, pyridine derivative salts such as pyridinium p-toluenesulfonate, and morpholine derivative salts.

The acids or the salts thereof may be used each alone or in combination of two or more. The amount thereof is usually within the range of 0.0001 to 20% by mass, preferably 0.0005 to 10% by mass, and more preferably 0.01 to 5% by mass relative to the total solid content.

Examples of the acid generators include thermal acid generators and photo acid generators. Examples of the thermal acid generators include 2,4,4,6-tetrabromocyclohexadienone, benzoin tosylate, 2-nitrobenzyl tosylate, K-PURE [registered trademark] series CXC-1612, CXC-1614, TAG-2172, TAG-2179, TAG-2678, TAG2689 and TAG2700 (manufactured by King Industries), SI-45, SI-60, SI-80, SI-100, SI-110 and SI-150 (manufactured by SANSHIN CHEMICAL INDUSTRY CO., LTD.), quaternary ammonium salt of trifluoroacetic acid, and other organic sulfonic acid alkyl esters.

The photo acid generator generates an acid when a resist is exposed to light, thereby allowing the acidity of the underlayer film to be adjusted. The use of the photo acid generator is an approach to adjusting the acidity of the underlayer film to the acidity of a resist layer that is formed thereon. Furthermore, the shape of a pattern formed in the upper resist layer may be controlled by the adjustment of the acidity of the underlayer film.

Examples of the photo acid generators used in the resist underlayer film-forming composition of the present invention include onium salt compounds, sulfonimide compounds and disulfonyldiazomethane compounds.

Examples of the onium salt compounds include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate and bis(4-tert-butylphenyl)iodonium trifluoromethanesulfonate, and sulfonium salt compounds such as triphenylsulfonium hexafluoroantimonate, triphenylsulfonium nonafluoro-n-butanesulfonate, triphenylsulfonium camphorsulfonate and triphenylsulfonium trifluoromethanesulfonate.

Examples of the sulfonimide compounds include N-(trifluoromethanesulfonyloxy)succinimide, N-(nonafluoro-n-butanesulfonyloxy)succinimide, N-(camphorsulfonyloxy)succinimide and N-(trifluoromethanesulfonyloxy)naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane and methylsulfonyl-p-toluenesulfonyldiazomethane.

The acid generators may be used each alone or in combination of two or more.

When the acid generator is used, the amount thereof is within the range of 0.01 to 5 parts by mass, or 0.1 to 3 parts by mass, or 0.5 to 1 part by mass, with respect to 100 parts by mass of the solid content in the resist underlayer film-forming composition.

[Additional Components]

A surfactant may be added to the resist underlayer film-forming composition of the present invention in order to prevent the occurrence of defects such as pinholes and striation and to further enhance the application properties with respect to uneven surfaces. Examples of the surfactant include nonionic surfactants, for example, polyoxyethylene alkyl ethers such as polyoxyethylene lauryl ether, polyoxyethylene stearyl ether, polyoxyethylene cetyl ether and polyoxyethylene oleyl ether; polyoxyethylene alkyl allyl ethers such as polyoxyethylene octyl phenol ether and polyoxyethylene nonyl phenol ether; polyoxyethylene/polyoxypropylene block copolymers; sorbitan fatty acid esters such as sorbitan monolaurate, sorbitan monopalmitate, sorbitan monostearate, sorbitan monooleate, sorbitan trioleate and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate; fluorine surfactants such as EFTOP series EF301, EF303 and EF352 (product names, manufactured by Tochem Products Co., Ltd.), MEGAFACE series F171, F173, R-40, R-40N and R-40LM (product names, manufactured by DIC CORPORATION), FLUORAD series FC430 and FC431 (product names, manufactured by Sumitomo 3M Ltd.), and ASAHI GUARD AG710 and SURFLON series S-382, SC101, SC102, SC103, SC104, SC105 and SC106 (product names, manufactured by AGC Inc.); and organosiloxane polymer KP341 (manufactured by Shin-Etsu Chemical Co., Ltd.). The amount of the surfactant is usually 2.0% by mass or less, and preferably 1.0% by mass or less relative to the total solid content in the resist underlayer film material. The surfactants may be used each alone or in combination of two or more. When the surfactant is used, the amount thereof is within the range of 0.0001 to 5 parts by mass, or 0.001 to 1 part by mass, or 0.01 to 0.5 part by mass, with respect to 100 parts by mass of the solid content in the resist underlayer film-forming composition.

Additives such as light absorbers, rheology modifiers and adhesion aids may be added to the resist underlayer film-forming composition of the present invention. Rheology modifiers are effective for enhancing the fluidity of the underlayer film-forming composition. Adhesion aids are effective for enhancing the adhesion between the underlayer film and a semiconductor substrate or a resist.

Some example light absorbers that may be suitably used are commercially available light absorbers described in “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; and C. I. Pigment Brown 2. The light absorber is usually added in a proportion of 10% by mass or less, preferably 5% by mass or less, relative to the total solid content in the resist underlayer film-forming composition.

The rheology modifier may be added mainly to enhance the fluidity of the resist underlayer film-forming composition and thereby, particularly in the baking step, to enhance the uniformity in thickness of the resist underlayer film and to increase the filling performance of the resist underlayer film-forming composition with respect to the inside of holes. Specific examples thereof include phthalic acid derivatives such as dimethyl phthalate, diethyl phthalate, diisobutyl phthalate, dihexyl phthalate and butyl isodecyl phthalate; adipic acid derivatives such as di-n-butyl adipate, diisobutyl adipate, diisooctyl adipate and octyl decyl adipate; maleic acid derivatives such as di-n-butyl maleate, diethyl maleate and dinonyl maleate; oleic acid derivatives such as methyl oleate, butyl oleate and tetrahydrofurfuryl oleate; and stearic acid derivatives such as n-butyl stearate and glyceryl stearate. The rheology modifier is usually added in a proportion of less than 30% by mass relative to the total solid content in the resist underlayer film-forming composition.

The adhesion aid may be added mainly to enhance the adhesion between the resist underlayer film-forming composition and a substrate or a resist and thereby to prevent the detachment of the resist particularly during development. Specific examples thereof include chlorosilanes such as trimethylchlorosilane, dimethylmethylolchlorosilane, methyldiphenylchlorosilane and chloromethyldimethylchlorosilane; alkoxysilanes such as trimethylmethoxysilane, dimethyldiethoxysilane, methyldimethoxysilane, dimethylmethylolethoxysilane, diphenyldimethoxysilane and phenyltriethoxysilane; silazanes such as hexamethyldisilazane, N,N′-bis(trimethylsilyl)urea, dimethyltrimethylsilylamine and trimethylsilylimidazole; silanes such as methyloltrichlorosilane, γ-chloropropyltrimethoxysilane, γ-aminopropyltriethoxysilane and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracyl, mercaptoimidazole and mercaptopyrimidine; and urea or thiourea compounds such as 1,1-dimethylurea and 1,3-dimethylurea. The adhesion aid is usually added in a proportion of less than 5% by mass, preferably less than 2% by mass, relative to the total solid content in the resist underlayer film-forming composition.

The solid content in the resist underlayer film-forming composition of the present invention is usually within the range of 0.1 to 70% by mass, and preferably 0.1 to 60% by mass. The solid content is the proportion of all the components constituting the resist underlayer film-forming composition except the solvent. The proportion of the reaction product in the solid content is within the range of 1 to 100% by mass, 1 to 99.9% by mass, 50 to 99.9% by mass, 50 to 95% by mass, or 50 to 90% by mass in the order of increasing preference.

One of the measures for evaluating whether the resist underlayer film-forming composition is a uniform solution is to pass the composition through a predetermined microfilter. The resist underlayer film-forming composition according to the present invention can be passed through a microfilter having a pore size of 0.1 μm, and exhibits a uniform solution state.

Examples of the microfilter materials include fluororesins such as PTFE (polytetrafluoroethylene) and PFA (tetrafluoroethylene/perfluoroalkyl vinyl ether copolymer), PE (polyethylene), UPE (ultrahigh molecular weight polyethylene), PP (polypropylene), PSF (polysulfone), PES (polyethersulfone) and nylon, with PTFE (polytetrafluoroethylene) being preferable.

[Resist Underlayer Film and Method for Manufacturing Semiconductor Device]

Hereinbelow, the resist underlayer film from the resist underlayer film-forming compositions of the present invention, and the method for manufacturing a semiconductor device will be described.

The resist underlayer film-forming composition of the present invention is applied with an appropriate technique such as a spinner or a coater onto a semiconductor device substrate (such as, for example, a silicon wafer substrate, a silicon dioxide substrate (a SiO₂ substrate), a silicon nitride substrate (a SiN substrate), a silicon oxynitride substrate (a SiON substrate), a titanium nitride substrate (a TiN substrate), a tungsten substrate (a W substrate), a glass substrate, an ITO substrate, a polyimide substrate or a low-dielectric constant material (low-k material)-coated substrate), and the coating is baked to form a resist underlayer film. The baking conditions are appropriately selected from baking temperatures of 80° C. to 500° C. and amounts of baking time of 0.3 to 60 minutes. The baking temperature is preferably within the range of 150° C. to 400° C., and the baking time is preferably within the range of 0.5 to 2 minutes. Here, the film thickness of the underlayer film that is formed is, for example, within the range of 10 to 1000 nm, or 20 to 500 nm, or 30 to 300 nm, or 50 to 200 nm.

Air or a nitrogen atmosphere may be selected as the baking atmosphere.

Furthermore, an inorganic resist underlayer film (a hard mask) may be formed on the organic resist underlayer film according to the present invention. For example, such a hard mask may be formed by spin coating a silicon-containing resist underlayer film (inorganic resist underlayer film)-forming composition described in WO 2009/104552 A1, or by CVD of a Si-based inorganic material.

The resist underlayer film-forming composition according to the present invention may be applied onto a semiconductor substrate having a stepped region and a stepless region (the so-called stepped substrate) and may be baked to form a resist underlayer film having a step height in the range of 3 to 50 nm between the stepped region and the stepless region.

Next, a resist film, for example, a photoresist layer is formed on the resist underlayer film. The photoresist layer may be formed by a well-known method, specifically, by applying a photoresist composition solution onto the underlayer film followed by baking. The film thickness of the photoresist is, for example, within the range of 50 to 10000 nm, or 100 to 2000 nm, or 200 to 1000 nm.

The photoresist applied onto the resist underlayer film is not particularly limited as long as it is sensitive to light used in the exposure. Negative photoresists and positive photoresists may be used. Examples include positive photoresists composed of a novolac resin and a 1,2-naphthoquinonediazide sulfonic acid ester; chemically amplified photoresists composed of a photo acid generator and a binder having a group that is decomposed by an acid to increase the alkali dissolution rate; chemically amplified photoresists composed of an alkali-soluble binder, a photo acid generator, and a low-molecular compound that is decomposed by an acid to increase the alkali dissolution rate of the photoresist; and chemically amplified photoresists composed of a photo acid generator, a binder having a group that is decomposed by an acid to increase the alkali dissolution rate, and a low-molecular compound that is decomposed by an acid to increase the alkali dissolution rate of the photoresist. Specific examples include those available under the product names of APEX-E from Shipley, PAR 710 from Sumitomo Chemical Co., Ltd., and SEPR 430 from Shin-Etsu Chemical Co., Ltd. Examples further include fluorine-containing polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Next, a resist pattern is formed by light or electron beam irradiation and development. First, the resist is exposed through a predetermined mask. For example, a near ultraviolet ray, a far ultraviolet ray, or an extreme ultraviolet ray (e.g., EUV (wavelength: 13.5 nm)) may be used for the exposure. Specifically, for example, KrF excimer laser beam (wavelength: 248 nm), ArF excimer laser beam (wavelength: 193 nm) or F₂ excimer laser beam (wavelength: 157 nm) may be used. Of these, ArF excimer laser beam (wavelength: 193 nm) and EUV (wavelength: 13.5 nm) are preferable. After the exposure, post-exposure baking may be performed as required. The post-exposure baking is performed under conditions appropriately selected from baking temperatures of 70° C. to 150° C. and amounts of baking time of 0.3 to 10 minutes.

In the present invention, as a resist, an electron beam lithographic resist may be used in place of the photoresist. The electron beam resists may be negative or positive. They include chemically amplified resists composed of an acid generator and a binder having a group that is decomposed by an acid to change the alkali dissolution rate; chemically amplified resists composed of an alkali-soluble binder, an acid generator, and a low-molecular compound that is decomposed by an acid to change the alkali dissolution rate of the resist; chemically amplified resists composed of an acid generator, a binder having a group that is decomposed by an acid to change the alkali dissolution rate, and a low-molecular compound that is decomposed by an acid to change the alkali dissolution rate of the resist; non-chemically amplified resists composed of a binder having a group that is decomposed by an electron beam to change the alkali dissolution rate, and non-chemically amplified resists composed of a binder having a moiety that is cleaved by an electron beam to change the alkali dissolution rate. The electron beam resist may be patterned using an electron beam as the irradiation source in the same manner as in the case where the photoresist is used.

Next, the resist is developed with a developing solution. When, for example, the resist is a positive photoresist, the portions of the photoresist that have been exposed are removed to leave a photoresist pattern.

Examples of the developing solution include alkaline aqueous solutions, for example, aqueous solutions of alkali metal hydroxides such as potassium hydroxide and sodium hydroxide; aqueous solutions of quaternary ammonium hydroxides such as tetramethylammonium hydroxide, tetraethylammonium hydroxide and choline; and aqueous solutions of amines such as ethanolamine, propylamine and ethylenediamine. Furthermore, additives such as surfactants may be added to the developing solutions. The development conditions are appropriately selected from temperatures of 5 to 50° C. and amounts of time of 10 to 600 seconds.

After the photoresist (the upper layer) has been patterned as described above, the inorganic underlayer film (the intermediate layer) is removed using the pattern as a protective film, and thereafter the organic underlayer film (the lower layer) is removed using as a protective film the film consisting of the patterned photoresist and the patterned inorganic underlayer film (intermediate layer). Lastly, the semiconductor substrate is processed using as a protective film the patterned inorganic underlayer film (intermediate layer) and the patterned organic underlayer film (lower layer).

First, the portions of the inorganic underlayer film (the intermediate layer) exposed from the photoresist are removed by dry etching to expose the semiconductor substrate. The dry etching of the inorganic underlayer film may be performed using a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane or dichloroborane. A halogen-containing gas is preferably used in the dry etching of the inorganic underlayer film, and a fluorine-containing gas is more preferably used. Examples of the fluorine-containing gases include tetrafluoromethane (CF₄), perfluorocyclobutane (C₄F₈), perfluoropropane (C₃F₈), trifluoromethane and difluoromethane (CH₂F₂).

Subsequently, the organic underlayer film is removed using as a protective film the film consisting of the patterned photoresist and the patterned inorganic underlayer film. The organic underlayer film (the lower layer) is preferably removed by dry etching using an oxygen-containing gas. This is because the inorganic underlayer film containing a large amount of silicon atoms is hardly removed by dry etching with an oxygen-containing gas.

Lastly, the semiconductor substrate is processed. The semiconductor substrate is preferably processed by dry etching with a fluorine-containing gas.

Examples of the fluorine-containing gases include tetrafluoromethane (CF₄), perfluorocyclobutane (C₄F₈), perfluoropropane (C₃F₈), trifluoromethane and difluoromethane (CH₂F₂).

Before the formation of the photoresist, an organic antireflective film may be formed as an upper layer on the resist underlayer films. The antireflective coating composition used herein is not particularly limited and may be appropriately selected from those conventionally used in the lithographic processes. The antireflective film may be formed by a conventional method, for example, by application with a spinner or a coater followed by baking.

In the present invention, an organic underlayer film may be formed on a substrate, thereafter an inorganic underlayer film may be formed thereon, and further a photoresist may be formed thereon. Even in the case where the photoresist is designed with a narrow pattern width and is formed with a small thickness to avoid collapsing of the pattern, the configuration described above in combination with selection of appropriate etching gases allows the substrate to be processed as designed. For example, the resist underlayer film may be processed using as the etching gas a fluorine-containing gas capable of etching the photoresist at a sufficiently high rate; the substrate may be processed using as the etching gas a fluorine-containing gas capable of etching the inorganic underlayer film at a sufficiently high rate; and further the substrate may be processed using as the etching gas an oxygen-containing gas capable of etching the organic underlayer film at a sufficiently high rate.

The resist underlayer film formed from the resist underlayer film-forming composition sometimes shows absorption with respect to the light used in the lithographic process, depending on the wavelength of the light. In such cases, the film can function as an antireflective film to effectively prevent the reflection of light from the substrate. Furthermore, the underlayer film formed from the resist underlayer film-forming composition of the present invention can also function as a hard mask. The underlayer film of the present invention may be used as, for example, a layer for preventing the interaction between a substrate and a photoresist, a layer having a function to prevent adverse effects on a substrate by a material used in a photoresist or by a substance generated during the exposure of a photoresist, a layer having a function to prevent the diffusion of substances generated from a substrate during heating and baking into an upper photoresist layer, and a barrier layer for reducing the poisoning effects on a photoresist layer by a semiconductor substrate dielectric layer.

Furthermore, the underlayer film formed from the resist underlayer film-forming composition may be used as a filling material that is applied to a via-hole substrate used in the dual damascene process and can fill the holes without clearance. Furthermore, the underlayer film may also be used as a flattening material for flattening the surface of an irregular semiconductor substrate.

### EXAMPLES

Hereinbelow, the present invention will be described in greater detail with reference to the examples and the like. However, it should be construed that the scope of the present invention is in no way limited to such examples and the like described below.

The following are the apparatus, etc. used in the measurement of the weight average molecular weight of compounds obtained in Synthesis Examples below.
Apparatus: HLC-8320 GPC manufactured by TOSOH CORPORATION
GPC columns: TSKgel Super-Multipore HZ-N (two columns)
Column temperature: 40° C.
Flow rate: 0.35 mL/min
Eluent: THF
Standard samples: Polystyrenes

### Synthesis Example 1

A flask was charged with 10.00 g of p-naphtholbenzein (manufactured by FUJIFILM Wako Pure Chemical Corporation), 4.17 g of 1-naphthaldehyde (manufactured by Tokyo Chemical Industry Co., Ltd.), 1.28 g of methanesulfonic acid (manufactured by Tokyo Chemical Industry Co., Ltd.) and 23.18 g of propylene glycol monomethyl ether acetate (hereinafter, written as PGMEA). Subsequently, the mixture was heated to reflux under nitrogen, and the reaction was performed for about 15 hours. After the reaction was terminated, the reaction product was precipitated in methanol and was dried, to obtain compound (1-1). The weight average molecular weight Mw measured by GPC relative to polystyrene was 450. The compound obtained was dissolved into PGMEA, and subjected to ion exchange treatment for 4 hours using a cation exchange resin and an anion exchange resin, to obtain the target compound solution.

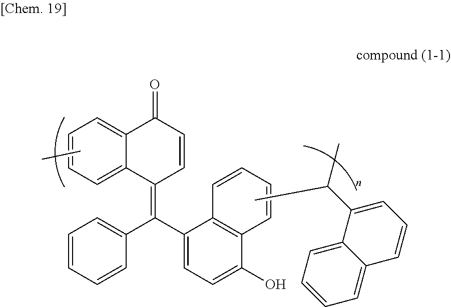

### Synthesis Example 2

8.00 g of a-naphtholbenzein (manufactured by FUJIFILM Wako Pure Chemical Corporation), 3.18 g of 1-naphthaldehyde (manufactured by Tokyo Chemical Industry Co., Ltd.), 0.98 g of methanesulfonic acid (manufactured by Tokyo Chemical Industry Co., Ltd.), 4.00 g of NMP and 18.24 g of PGMEA were charged. Subsequently, the mixture was heated to reflux under nitrogen, and the reaction was performed for about 15 hours. After the reaction was terminated, the reaction product was precipitated in methanol and was dried, to obtain compound (1-2). The weight average molecular weight Mw measured by GPC relative to polystyrene was 450. The compound obtained was dissolved into PGMEA, and subjected to ion exchange treatment for 4 hours using a cation exchange resin and an anion exchange resin, to obtain the target compound solution.

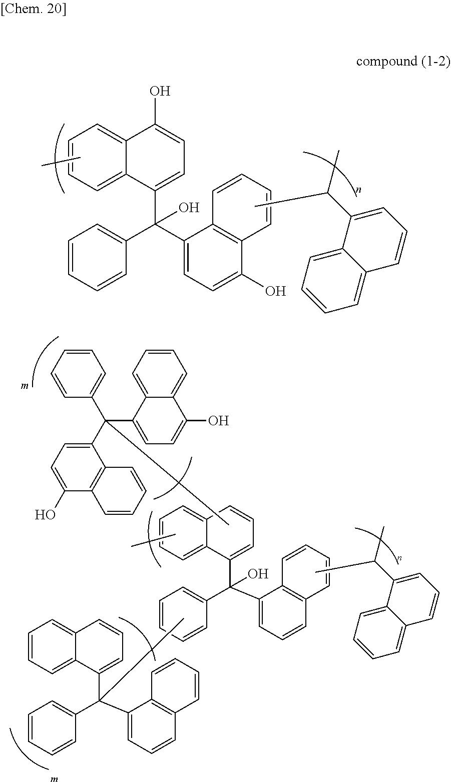

### Synthesis Example 3

A flask was charged with 5.00 g of p-naphtholbenzein (manufactured by FUJIFILM Wako Pure Chemical Corporation), 3.07 g of 1-pyrenecarboxyaldehyde, 0.64 g of methanesulfonic acid (manufactured by Tokyo Chemical Industry Co., Ltd.) and 13.07 g of PGMEA. Subsequently, the mixture was heated to reflux under nitrogen, and the reaction was performed for about 15 hours. After the reaction was terminated, the reaction product was precipitated in methanol and was dried, to obtain compound (1-3). The weight average molecular weight Mw measured by GPC relative to polystyrene was 520. The compound obtained was dissolved into cyclohexanone, and subjected to ion exchange treatment for 4 hours using a cation exchange resin and an anion exchange resin, to obtain the target compound solution.

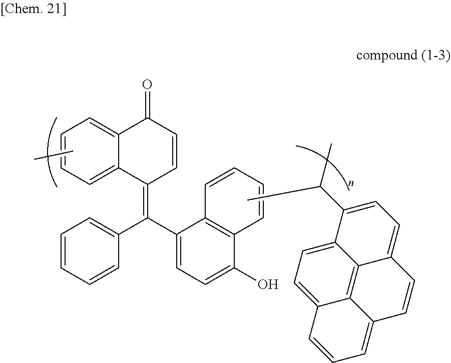

### Synthesis Example 4

A flask was charged with 5.00 g of p-naphtholbenzein (manufactured by FUJIFILM Wako Pure Chemical Corporation), 2.41 g of 9-fluorenone (manufactured by Tokyo Chemical Industry Co., Ltd.), 0.64 g of methanesulfonic acid (manufactured by Tokyo Chemical Industry Co., Ltd.) and 12.07 g of PGMEA. Subsequently, the mixture was heated to reflux under nitrogen, and the reaction was performed for about 15 hours. After the reaction was terminated, the reaction product was precipitated in methanol and was dried, to obtain compound (1-4). The weight average molecular weight Mw measured by GPC relative to polystyrene was 800. The compound obtained was dissolved into PGMEA, and subjected to ion exchange treatment for 4 hours using a cation exchange resin and an anion exchange resin, to obtain the target compound solution.

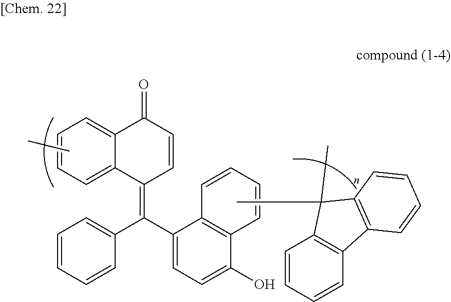

### Synthesis Example 5

A flask was charged with 8.00 g of a-naphtholbenzein (manufactured by FUJIFILM Wako Pure Chemical Corporation), 3.67 g of 9-fluorenone (manufactured by Tokyo Chemical Industry Co., Ltd.), 1.96 g of methanesulfonic acid (manufactured by Tokyo Chemical Industry Co., Ltd.), 1.36 g of NMP and 12.27 g of PGMEA. Subsequently, the mixture was heated to reflux under nitrogen, and the reaction was performed for about 15 hours. After the reaction was terminated, the reaction product was precipitated in methanol and was dried, to obtain compound (1-5). The weight average molecular weight Mw measured by GPC relative to polystyrene was 470. The compound obtained was dissolved into PGMEA, and subjected to ion exchange treatment for 4 hours using a cation exchange resin and an anion exchange resin, to obtain the target compound solution.

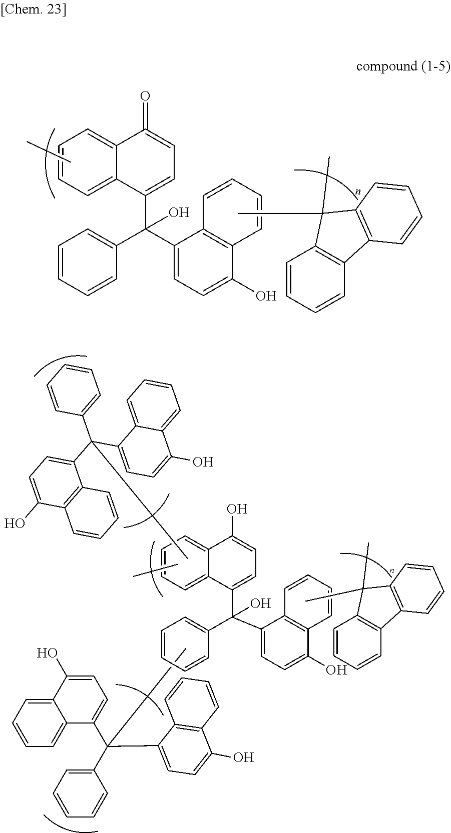

### Synthesis Example 6

A flask was charged with 4.67 g of p-naphtholbenzein (manufactured by FUJIFILM Wako Pure Chemical Corporation), 5.00 g of carbazole (manufactured by Tokyo Chemical Industry Co., Ltd.), 1.44 g of methanesulfonic acid (manufactured by Tokyo Chemical Industry Co., Ltd.) and 16.66 g of PGMEA. Subsequently, the mixture was heated to reflux under nitrogen, and the reaction was performed for about 9 hours. After the reaction was terminated, the reaction product was precipitated in methanol and was dried, to obtain compound (1-6). The weight average molecular weight Mw measured by GPC relative to polystyrene was 3,550. The compound obtained was dissolved into PGMEA, and subjected to ion exchange treatment for 4 hours using a cation exchange resin and an anion exchange resin, to obtain the target compound solution.

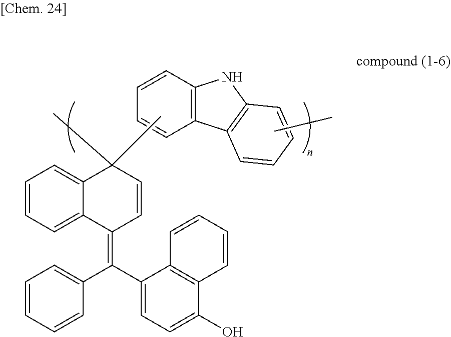

### Synthesis Example 7

A flask was charged with 3.56 g of p-naphtholbenzein (manufactured by FUJIFILM Wako Pure Chemical Corporation), 5.00 g of N-phenyl-1-naphthylamine (manufactured by Tokyo Chemical Industry Co., Ltd.), 1.10 g of methanesulfonic acid (manufactured by Tokyo Chemical Industry Co., Ltd.) and 14.48 g of PGMEA. Subsequently, the mixture was heated to reflux under nitrogen, and the reaction was performed for 22 hours. After the reaction was terminated, the reaction product was precipitated in methanol and was dried, to obtain compound (1-7). The weight average molecular weight Mw measured by GPC relative to polystyrene was 1,450. The compound obtained was dissolved into PGMEA, and subjected to ion exchange treatment for 4 hours using a cation exchange resin and an anion exchange resin, to obtain the target compound solution.

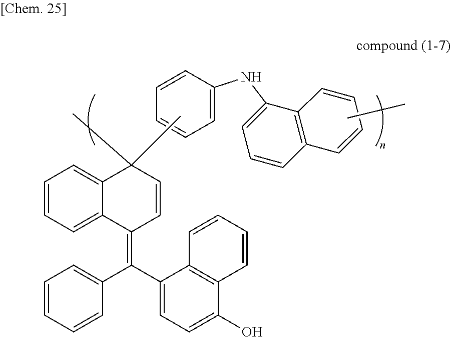

### Synthesis Example 8

A flask was charged with 9.69 g of p-naphtholbenzein (manufactured by FUJIFILM Wako Pure Chemical Corporation), 5.00 g of 2-phenylindole (manufactured by Tokyo Chemical Industry Co., Ltd.), 1.24 g of methanesulfonic acid (manufactured by Tokyo Chemical Industry Co., Ltd.) and 23.90 g of PGMEA. Subsequently, the mixture was heated to reflux under nitrogen, and the reaction was performed for 21 hours. After the reaction was terminated, the reaction product was precipitated in methanol and water, and was dried, to obtain compound (1-8). The weight average molecular weight Mw measured by GPC relative to polystyrene was 1,000. The compound obtained was dissolved into PGMEA, and subjected to ion exchange treatment for 4 hours using a cation exchange resin and an anion exchange resin, to obtain the target compound solution.

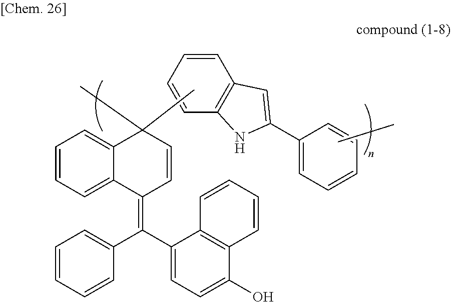

### Synthesis Example 9

A flask was charged with 9.05 g of p-naphtholbenzein (manufactured by FUJIFILM Wako Pure Chemical Corporation), 4.50 g of 2,2′-biphenol, 1.16 g of methanesulfonic acid (manufactured by Tokyo Chemical Industry Co., Ltd.) and 22.07 g of PGMEA. Subsequently, the mixture was heated to reflux under nitrogen, and the reaction was performed for 21 hours. After the reaction was terminated, the reaction product was precipitated in methanol and water, and was dried, to obtain compound (1-9). The weight average molecular weight Mw measured by GPC relative to polystyrene was 900. The compound obtained was dissolved into PGMEA, and subjected to ion exchange treatment for 4 hours using a cation exchange resin and an anion exchange resin, to obtain the target compound solution.

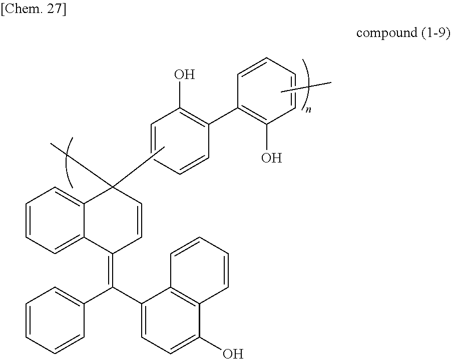

### Synthesis Example 10

A flask was charged with 10.52 g of p-naphtholbenzein (manufactured by FUJIFILM Wako Pure Chemical Corporation), 4.50 g of 1,5-dihydroxynaphthalene (manufactured by Tokyo Chemical Industry Co., Ltd.), 1.35 g of methanesulfonic acid (manufactured by Tokyo Chemical Industry Co., Ltd.) and 24.55 g of PGMEA. Subsequently, the mixture was heated to reflux under nitrogen, and the reaction was performed for 21 hours. After the reaction was terminated, the reaction product was precipitated in methanol and water, and was dried, to obtain compound (1-10). The weight average molecular weight Mw measured by GPC relative to polystyrene was 600. The compound obtained was dissolved into propylene glycol monomethyl ether (hereinafter, written as PGME), and subjected to ion exchange treatment for 4 hours using a cation exchange resin and an anion exchange resin, to obtain the target compound solution.

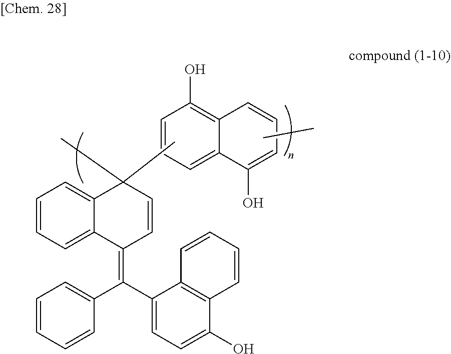

### Synthesis Example 11

A flask was charged with 7.48 g of p-naphtholbenzein (manufactured by FUJIFILM Wako Pure Chemical Corporation), 7.00 g of 9,9-bis(4-hydroxyphenyl)fluorene (manufactured by Tokyo Chemical Industry Co., Ltd.), 0.96 g of methanesulfonic acid (manufactured by Tokyo Chemical Industry Co., Ltd.) and 23.16 g of PGMEA. Subsequently, the mixture was heated to reflux under nitrogen, and the reaction was performed for 21 hours. After the reaction was terminated, the reaction product was precipitated in methanol and water, and was dried, to obtain compound (1-11). The weight average molecular weight Mw measured by GPC relative to polystyrene was 800. The compound obtained was dissolved into PGMEA, and subjected to ion exchange treatment for 4 hours using a cation exchange resin and an anion exchange resin, to obtain the target compound solution.

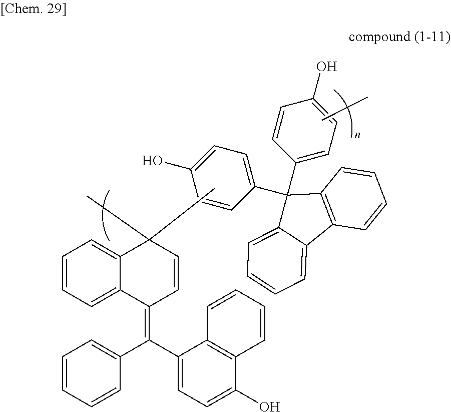

### Comparative Synthesis Example 1

A flask was charged with 15.00 g of 2,2′-biphenol (manufactured by Tokyo Chemical Industry Co., Ltd.), 12.58 g of 1-naphthaldehyde (manufactured by Tokyo Chemical Industry Co., Ltd.), 1.94 g of methanesulfonic acid (manufactured by Tokyo Chemical Industry Co., Ltd.) and 29.58 g of PGMEA. Subsequently, the mixture was heated to reflux under nitrogen, and the reaction was performed for about 14 hours. After the reaction was terminated, the reaction product was precipitated in methanol and was dried, to obtain compound (2-1). The weight average molecular weight Mw measured by GPC relative to polystyrene was 5,500. The compound obtained was dissolved into PGME, and subjected to ion exchange treatment for 4 hours using a cation exchange resin and an anion exchange resin, to obtain the target compound solution.

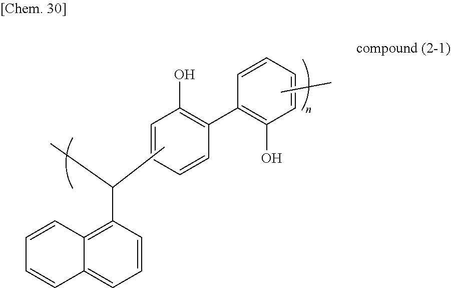

### Comparative Synthesis Example 2

A flask was charged with 10.00 g of 2,2′-biphenol (manufactured by Tokyo Chemical Industry Co., Ltd.), 9.68 g of 9-fluorenone (manufactured by Tokyo Chemical Industry Co., Ltd.), 2.58 g of methanesulfonic acid (manufactured by Tokyo Chemical Industry Co., Ltd.) and 33.39 g of PGMEA. Subsequently, the mixture was heated to reflux under nitrogen, and the reaction was performed for about 12.5 hours. After the reaction was terminated, the reaction product was precipitated in methanol and water, and was dried, to obtain compound (2-2). The weight average molecular weight Mw measured by GPC relative to polystyrene was 1,700. The compound obtained was dissolved into PGMEA, and subjected to ion exchange treatment for 4 hours using a cation exchange resin and an anion exchange resin, to obtain the target compound solution.

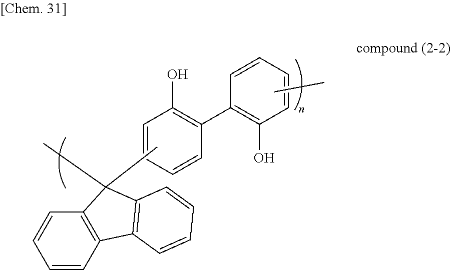

### Example 1

The compound solution (solid content: 20.96% by mass) was obtained in Synthesis Example 1. To 6.20 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 7.85 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

### Example 2

The compound solution (solid content: 13.88% by mass) was obtained in Synthesis Example 2. To 8.78 g of this compound solution were added 0.24 g of TMOM-BP (manufactured by Honshu Chemical Industry Co., Ltd.), 1.83 g of a 2% by mass PGME solution of pyridinium p-hydroxybenzenesulfonate, 0.12 g of a 1% by mass PGMEA solution of a surfactant (MEGAFACE R-40 manufactured by DIC CORPORATION), 0.42 g of PGMEA, 0.91 g of PGME and 2.70 g of cyclohexanone, and dissolved. The resultant solution was filtered through a polytetrafluoroethylene microfilter having a pore size of 0.1 μm, to prepare a solution of a resist underlayer film-forming composition.

### Example 3

The compound solution (solid content: 15.50% by mass) was obtained in Synthesis Example 3. To 8.39 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 7.23 g of PGMEA, 1.77 g of PGME and 0.27 g of cyclohexanone, and dissolved. The resultant solution was filtered through a polytetrafluoroethylene microfilter having a pore size of 0.1 μm, to prepare a solution of a resist underlayer film-forming composition.

### Example 4

The compound solution (solid content: 13.82% by mass) was obtained in Synthesis Example 4. To 9.40 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 4.65 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

### Example 5

The compound solution (solid content: 16.39% by mass) was obtained in Synthesis Example 5. To 7.43 g of this compound solution were added 0.24 g of TMOM-BP (manufactured by Honshu Chemical Industry Co., Ltd.), 1.83 g of a 2% by mass PGME solution of pyridinium p-hydroxybenzenesulfonate, 0.12 g of a 1% by mass PGMEA solution of a surfactant (MEGAFACE R-40 manufactured by DIC CORPORATION), 0.41 g of PGMEA, 0.91 g of PGME and 4.05 g of cyclohexanone, and dissolved. The resultant solution was filtered through a polytetrafluoroethylene microfilter having a pore size of 0.1 μm, to prepare a solution of a resist underlayer film-forming composition.

### Example 6

The compound solution (solid content: 14.09% by mass) was obtained in Synthesis Example 6. To 9.22 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 4.83 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

### Example 7

The compound solution (solid content: 12.37% by mass) was obtained in Synthesis Example 7. To 9.19 g of this compound solution were added 0.23 g of TMOM-BP (manufactured by Honshu Chemical Industry Co., Ltd.), 1.71 g of a 2% by mass PGME solution of pyridinium p-hydroxybenzenesulfonate, 0.11 g of a 1% by mass PGMEA solution of a surfactant (MEGAFACE R-40 manufactured by DIC CORPORATION), 4.85 g of PGMEA and 3.91 g of PGME, and dissolved. The resultant solution was filtered through a polytetrafluoroethylene microfilter having a pore size of 0.1 μm, to prepare a solution of a resist underlayer film-forming composition.

### Example 8

The compound solution (solid content: 17.46% by mass) was obtained in Synthesis Example 8. To 7.44 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 6.61 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

### Example 9

The compound solution (solid content: 18.75% by mass) was obtained in Synthesis Example 9. To 6.93 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 7.12 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

### Example 10

The compound solution (solid content: 18.01% by mass) was obtained in Synthesis Example 10. To 7.22 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 5.39 g of PGMEA and 5.05 g of PGME, and dissolved. The resultant solution was filtered through a polytetrafluoroethylene microfilter having a pore size of 0.1 μm, to prepare a solution of a resist underlayer film-forming composition.

### Example 11

The compound solution (solid content: 18.50% by mass) was obtained in Synthesis Example 11. To 7.03 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 7.03 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

### Comparative Example 1

The compound solution (solid content: 22.44% by mass) was obtained in Comparative Synthesis Example 1. To 5.79 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 5.39 g of PGMEA and 6.48 g of PGME, and dissolved. The resultant solution was filtered through a polytetrafluoroethylene microfilter having a pore size of 0.1 μm, to prepare a solution of a resist underlayer film-forming composition.

### Comparative Example 2

The compound solution (solid content: 19.00% by mass) was obtained in Comparative Synthesis Example 1. To 6.84 g of this compound solution were added 0.26 g of TMOM-BP (manufactured by Honshu Chemical Industry Co., Ltd.), 1.95 g of a 2% by mass PGME solution of pyridinium p-hydroxybenzenesulfonate, 0.13 g of a 1% by mass PGMEA solution of a surfactant (MEGAFACE R-40 manufactured by DIC CORPORATION), 7.21 g of PGMEA and 3.61 g of PGME, and dissolved. The resultant solution was filtered through a polytetrafluoroethylene microfilter having a pore size of 0.1 μm, to prepare a solution of a resist underlayer film-forming composition.

(Test of Dissolution into Resist Solvent)

Each of the solutions of a resist underlayer film-forming composition prepared in Comparative Examples 1 and 2 and Examples 1 to 11 was applied onto a silicon wafer using a spin coater, and the coating was baked on a hot plate at 350° C. for 60 seconds, to form a resist underlayer film (film thickness: 150 nm). The resist underlayer films were soaked in a general-purpose thinner, specifically, PGME/PGMEA=7/3. The resist underlayer films were insoluble, thus showing sufficient curability.

(Measurement of Optical Constants)

Each of the solutions of a resist underlayer film-forming composition prepared in Comparative Examples 1 and 2 and Examples 1 to 11 was applied onto a silicon wafer using a spin coater. The coating was baked on a hot plate at 350° C. for 60 seconds, to form a resist underlayer film (film thickness: 50 nm). With regard to these resist underlayer films, the refractive index (n value) and optical absorption coefficient (k value, also called the attenuation coefficient) at a wavelength of 193 nm were determined with a spectroscopic ellipsometer (Table 1).

TABLE 1
Refractive index n and optical absorption coefficient k

| | | n/k 193 nm |
|---|---|---|
| Comparative Example1 | Film baked at 350° C. | 1.34/0.46 |
| Comparative Example2 | Film baked at 350° C. | 1.42/0.48 |
| Example1 | Film baked at 350° C. | 1.43/0.51 |
| Example2 | Film baked at 350° C. | 1.43/0.51 |
| Example3 | Film baked at 350° C. | 1.49/0.58 |
| Example4 | Film baked at 350° C. | 1.48/0.51 |
| Example5 | Film baked at 350° C. | 1.47/0.52 |
| Example6 | Film baked at 350° C. | 1.45/0.39 |
| Example7 | Film baked at 350° C. | 1.39/0.47 |
| Example8 | Film baked at 350° C. | 1.50/0.52 |
| Example9 | Film baked at 350° C. | 1.46/0.52 |
| Example10 | Film baked at 350° C. | 1.45/0.48 |
| Example11 | Film baked at 350° C. | 1.44/0.56 |

Comparing Comparative Example 1 with Example 1, and Comparative Example 2 with Example 4 and Example 9, respectively, shows that it is possible to elevate n value in Examples. Moreover, as demonstrated in the other Examples, the optical constants can largely be changed by changing the type of compounds that are combined.

### [Measurement of Dry Etching Rate]

The etcher and etching gas used for the determination of dry etching rate were as follows:

### RIE-10NR (Manufactured by Samco) and CF₄

Each of the solutions of a resist underlayer film-forming composition prepared in Comparative Examples 1 and 2 and Examples 1 to 11 was applied onto a silicon wafer using a spin coater. The coating was baked on a hot plate at 350° C. for 60 seconds to form a resist underlayer film (film thickness: 150 nm). The dry etching rate was determined using CF₄ gas as the etching gas. The dry etching rate of each of Comparative Examples 1 and 2 and Examples 1 to 11 was expressed as a dry etching rate ratio of (resist underlayer film)/(KrF photoresist) (Table 2).

TABLE 2
Dry etching rate ratio

| | | Etching rate |
|---|---|---|
| Comparative Example 1 | Film baked at 350° C. | 0.84 |
| Comparative Example 2 | Film baked at 350° C. | 1.05 |
| Example 1 | Film baked at 350° C. | 0.78 |
| Example 2 | Film baked at 350° C. | 0.80 |
| Example 3 | Film baked at 350° C. | 0.76 |
| Example 4 | Film baked at 350° C. | 0.78 |
| Example 5 | Film baked at 350° C. | 0.78 |
| Example 6 | Film baked at 350° C. | 0.79 |
| Example 7 | Film baked at 350° C. | 0.82 |
| Example 8 | Film baked at 350° C. | 0.82 |
| Example 9 | Film baked at 350° C. | 0.87 |
| Example 10 | Film baked at 350° C. | 0.88 |
| Example 11 | Film baked at 350° C. | 0.81 |

Comparing Comparative Example 1 with Example 1, and Comparative Example 2 with Example 4 and Example 9, respectively, shows that higher etching rates are attained in Examples. Moreover, as demonstrated in the other Examples, the etching resistance can largely be changed by changing the type of compounds that are combined.

(Evaluation of Gap-Filling Property)

Gap-filling property was evaluated using a 200 nm thick SiO₂ substrate that had a dense pattern area consisting of 50 nm wide trenches at 100 nm pitches. Each of the resist underlayer film-forming compositions prepared in Comparative Examples 1 and 2 and Examples 1 to 11 was applied onto the substrate, and the coating was baked at 350° C. for 60 seconds to form a resist underlayer film having a thickness of about 150 nm. The flatness of the substrates was evaluated using a scanning electron microscope (S-4800) manufactured by Hitachi High-Tech Corporation, and whether the resist underlayer film-forming composition had filled the inside of the pattern was confirmed (Table 3).

TABLE 3
Evaluation of gap-filling property

| | | Gap-filling property |
|---|---|---|
| Comparative Example 1 | Film baked at 350° C. | ◯ |
| Comparative Example 2 | Film baked at 350° C. | ◯ |
| Example 1 | Film baked at 350° C. | ◯ |
| Example 2 | Film baked at 350° C. | ◯ |
| Example 3 | Film baked at 350° C. | ◯ |
| Example 4 | Film baked at 350° C. | ◯ |
| Example 5 | Film baked at 350° C. | ◯ |
| Example 6 | Film baked at 350° C. | ◯ |
| Example 7 | Film baked at 350° C. | ◯ |
| Example 8 | Film baked at 350° C. | ◯ |
| Example 9 | Film baked at 350° C. | ◯ |
| Example 10 | Film baked at 350° C. | ◯ |
| Example 11 | Film baked at 350° C. | ◯ |

Examples exhibited a high gap-filling property as the conventional materials.

### INDUSTRIAL APPLICABILITY

According to the present invention, there is provided a resist underlayer film-forming composition capable of forming a flat film exhibiting a high etching resistance, good dry etching rate ratio and optical constants, having a high coatability even with respect to the so-called stepped substrate, and providing a small variation in film thickness after filling the gaps. Also according to the present invention, there are provided a method for producing a polymer suitably used in the resist underlayer film-forming composition, a resist underlayer film using the resist underlayer film-forming composition, and a process for the manufacture of a semiconductor device.

1. A resist underlayer film-forming composition comprising a solvent and a reaction product of a C6-C120 aromatic compound (A) with a compound represented by formula (1) below, 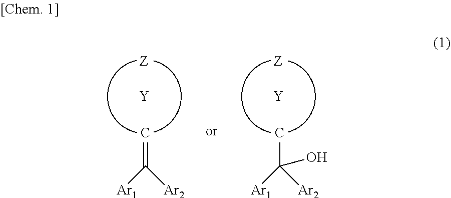
[in formula (1), Z denotes —(C═O)— or —C(—OH)—; Ar₁ and Ar₂ each independently denote an optionally substituted phenyl, naphthyl, anthracenyl or pyrenyl group; and ring Y denotes an optionally substituted cyclic aliphatic, an optionally substituted aromatic, or an optionally substituted cyclic aliphatic-aromatic fused ring.].

2. The resist underlayer film-forming composition according to claim 1, wherein the reaction product is such that one carbon atom in ring Y is linked to one molecule of aromatic compound (A), and one carbon atom in Ar₁ or Ar₂ is linked to another molecule of aromatic compound (A).

3. The resist underlayer film-forming composition according to claim 1, wherein the compound represented by formula (1) is represented by formula (1a) below: 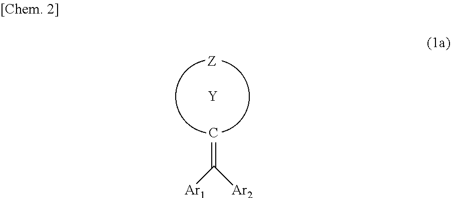
[in formula (1a), Z denotes —(C═O)—; Ar₁ and Ar₂ each independently denote an optionally substituted phenyl, naphthyl, anthracenyl or pyrenyl group; and ring Y denotes an optionally substituted cyclic aliphatic, or an optionally substituted cyclic aliphatic-aromatic fused ring.].

4. The resist underlayer film-forming composition according to claim 1, wherein the reaction product is such that one carbon atom in ring Y is linked to two molecules of aromatic compound (A).

5. The resist underlayer film-forming composition according to claim 4, wherein ring Y in formula (1a) is a fused ring structure containing a cyclohexene ring.

6. The resist underlayer film-forming composition according to claim 5, wherein ring Y in formula (1a) denotes a cyclic aliphatic-aromatic fused ring.

7. The resist underlayer film-forming composition according to claim 1, wherein the compound represented by formula (1) is represented by formula (1b) below: 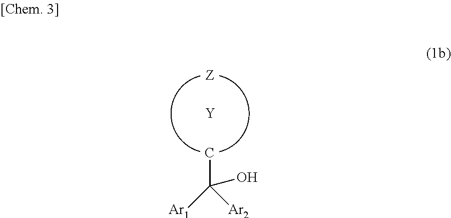
[in formula (1b), Z denotes —C(—OH)—; Ar₁ and Ar₂ each independently denote an optionally substituted phenyl, naphthyl, anthracenyl or pyrenyl group; and ring Y denotes an optionally substituted cyclic aliphatic, an optionally substituted aromatic, or an optionally substituted cyclic aliphatic-aromatic fused ring.].

8. The resist underlayer film-forming composition according to claim 7, wherein formula (1b) is an aromatic compound.

9. The resist underlayer film-forming composition according to claim 8, wherein Y in formula (1b) comprises a naphthalene ring.

10. The resist underlayer film-forming composition according to claim 1, wherein Ar₁ and Ar₂ in formula (1) each independently denote an optionally hydroxy-substituted phenyl or naphthyl group.

11. The resist underlayer film-forming composition according to claim 1, wherein aromatic compound (A) comprises at least one benzene ring, at least one naphthalene ring, at least one anthracene ring, at least one pyrene ring, or a combination thereof.

12. The resist underlayer film-forming composition according to claim 1, wherein aromatic compound (A) comprises at least two benzene rings, at least two naphthalene rings, at least two anthracene rings, at least two pyrene rings, or a combination thereof.

13. The resist underlayer film-forming composition according to claim 1, further comprising a crosslinking agent.

14. The resist underlayer film-forming composition according to claim 1, further comprising an acid and/or an acid generator.

15. The resist underlayer film-forming composition according to claim 1, wherein the solvent has a boiling point of 160° C. or above.

16. A resist underlayer film is a baked product of a coating film comprising the resist underlayer film-forming composition according to claim 1.

17. A method for manufacturing a semiconductor device, comprising the steps of:
forming on a semiconductor substrate a resist underlayer film using the resist underlayer film-forming composition according to claim 1;
forming a resist film on the resist underlayer film;
forming a resist pattern by irradiation with light or electron beam followed by development;
etching the underlayer film through the resist pattern; and
processing the semiconductor substrate through the patterned underlayer film.

18. The method for manufacturing a semiconductor device according to claim 17, wherein the step of forming a resist underlayer film is performed by a nanoimprinting method.
